(19) United States
(12) Patent Application Publication
(10) Pub. No.: US 2024/0341094 A1
(43) Pub. Date: Oct. 10, 2024

(54) SEMICONDUCTOR DEVICES AND ELECTRONIC SYSTEMS INCLUDING THE SAME

(71) Applicant: Samsung Electronics Co., Ltd., Suwon-si (KR)

(72) Inventors: Jiyoun Seo, Suwon-si (KR); Daeho Kim, Suwon-si (KR); Su Jong Kim, Suwon-si (KR); Sangho Rha, Suwon-si (KR); Byung-Sun Park, Suwon-si (KR); Mingyu Jeon, Suwon-si (KR)

(21) Appl. No.: 18/522,352

(22) Filed: Nov. 29, 2023

(30) Foreign Application Priority Data
Apr. 7, 2023 (KR) 10-2023-0045816

(51) Int. Cl. H10B 43/27; G11C 16/04; H01L 23/522; H01L 23/528; H01L 25/065; H10B 41/10; H10B 41/27; H10B 41/35; H10B 41/40; H10B 43/10; H10B 43/35; H10B 43/40; H10B 80/00

(52) U.S. Cl. CPC H10B 43/27; G11C 16/0483; H01L 23/5226; H01L 23/5283; H01L 25/0652; H10B 41/10; H10B 41/27; H10B 41/35; H10B 41/40; H10B 43/10; H10B 43/35; H10B 43/40; H10B 80/00; H01L 2225/0651

(57) ABSTRACT

A semiconductor device may include a substrate including a cell array region and a connection region, a stack including electrodes, which are vertically stacked on the substrate, and which have a staircase structure in the connection region, channel regions provided on the cell array region that vertically extend through the stack, and a planarization insulating layer that covers the stack in the connection region. The planarization insulating layer may include a first insulating layer in contact with the stack and a second insulating layer that covers the first insulating layer. The first insulating layer may include high-density plasma (HDP) oxide, which is doped with first dopants, and the second insulating layer may include tetraethyl orthosilicate (TEOS) oxide, which is doped with second dopants.

### CROSS-REFERENCE TO RELATED APPLICATION

This U.S. non-provisional patent application claims priority under 35 U.S.C. § 119 to Korean Patent Application No. 10-2023-0045816, filed on Apr. 7, 2023, in the Korean Intellectual Property Office, the entire contents of which are hereby incorporated by reference.

### TECHNICAL FIELD

The present disclosure relates to semiconductor devices and to electronic systems including semiconductor devices.

### BACKGROUND

In order to satisfy increasing consumer demands for superior performance and inexpensive prices, there has been great interest in increasing an integration density of semiconductor devices. Since the integration density of semiconductor devices is an important factor in determining product prices, increasing an integration density of semiconductor devices may provide greater performance characteristics and/or lower costs. In the case of two-dimensional or planar semiconductor devices, since their integration is mainly determined by the area occupied by a unit memory cell, integration is greatly influenced by the level of a fine pattern forming technology. However, the extremely expensive process equipment needed to increase pattern fineness sets a practical limitation on increasing integration for two-dimensional or planar semiconductor devices. Thus, three-dimensional semiconductor devices, in which memory cells are three-dimensionally arranged, have recently been proposed.

### SUMMARY

Some embodiments of the present inventive concepts provide semiconductor devices with improved structural stability.

Some embodiments of the inventive concepts provide methods of reducing a failure in a process of fabricating a semiconductor device.

According to some embodiments of the inventive concepts, a semiconductor device may include a substrate including a cell array region and a connection region, a stack including electrodes, which may be vertically stacked on the substrate, and which may have a staircase structure in the connection region, channel regions provided on the cell array region and vertically extend through the stack, and a planarization insulating layer that covers the stack in the connection region. The planarization insulating layer may include a first insulating layer in contact with the stack and a second insulating layer that covers the first insulating layer. The first insulating layer may include high-density plasma (HDP) oxide, which is doped with first dopants, and the second insulating layer may include tetraethyl orthosilicate (TEOS) oxide, which is doped with second dopants.

According to some embodiments of the inventive concepts, a semiconductor device may include a substrate including a cell array region and a connection region, a stack including electrodes and insulating patterns, which are vertically and alternately stacked on the substrate, an end portion of the stack on the connection region having a staircase structure, channel regions vertically extending through the stack, in the cell array region, a planarization insulating layer that covers the stack, in the connection region, penetration plugs provided on the connection region and vertically extend through the planarization insulating layer and connected to the electrodes, and interconnection patterns on the planarization insulating layer and connected to the penetration plugs. The planarization insulating layer may include a first insulating layer that covers a top surface of the substrate and the end portion of the stack, and a second insulating layer, which is on the first insulating layer and is spaced apart from the stack by the first insulating layer. An interface between the first insulating layer and the second insulating layer may have a wavy shape, and a density of the first insulating layer may be higher than a density of the second insulating layer.

According to some embodiments of the inventive concepts, an electronic system may include a semiconductor device including a substrate including a cell array region and a connection region, a stack including electrodes, which may be vertically stacked on the substrate, and having a staircase structure on the connection region, a plurality of channel regions, which are provided on the cell array region and vertically extend through the stack, a planarization insulating layer that covers the stack, and an input/output pad electrically connected to a peripheral circuit, and a controller, which is electrically connected to the semiconductor device through the input/output pad and is configured to control the semiconductor device. The planarization insulating layer may include a first insulating layer that covers the staircase structure of the stack and a second insulating layer on the first insulating layer and spaced apart from the stack by the first insulating layer. A density of the first insulating layer may be higher than a density of the second insulating layer, and a thickness of the first insulating layer may be larger than a thickness of one stepped portion of the staircase structure of the stack. The first insulating layer and the second insulating layer may include different materials from each other.

### BRIEF DESCRIPTION OF THE DRAWINGS

FIG. 1 is a diagram schematically illustrating an electronic system including a semiconductor device according to an embodiment of the inventive concept.

FIG. 2 is a perspective view schematically illustrating an electronic system including a semiconductor device according to an embodiment of the inventive concept.

FIGS. 3 and 4 are sectional views, each of which schematically illustrates a semiconductor package according to an embodiment of the inventive concept.

FIG. 5 is a schematic perspective view illustrating a semiconductor device according to an embodiment of the inventive concept.

FIG. 6 is a circuit diagram illustrating a cell array of a semiconductor device according to an embodiment of the inventive concept.

FIGS. 7 and 8 are plan views, each of which schematically illustrates a semiconductor device according to an embodiment of the inventive concept.

FIG. 9 is a plan view illustrating a semiconductor device according to an embodiment of the inventive concept.

FIGS. 10A, 11A, 12A, 13A, and 14A are sectional views, each of which illustrates a semiconductor device according to some embodiments of the inventive concepts.

FIGS. 10B, 11B, 12B, 13B, and 14B are enlarged sectional views illustrating portions of the semiconductor devices of FIGS. 10A, 11A, 12A, 13A, and 14A, respectively.

FIGS. 15 to 18 are sectional views, each of which illustrates a semiconductor device according to an embodiment of the inventive concept.

FIGS. 19 to 24 are sectional views illustrating a method of fabricating a semiconductor device, according to an embodiment of the inventive concept.

### DETAILED DESCRIPTION

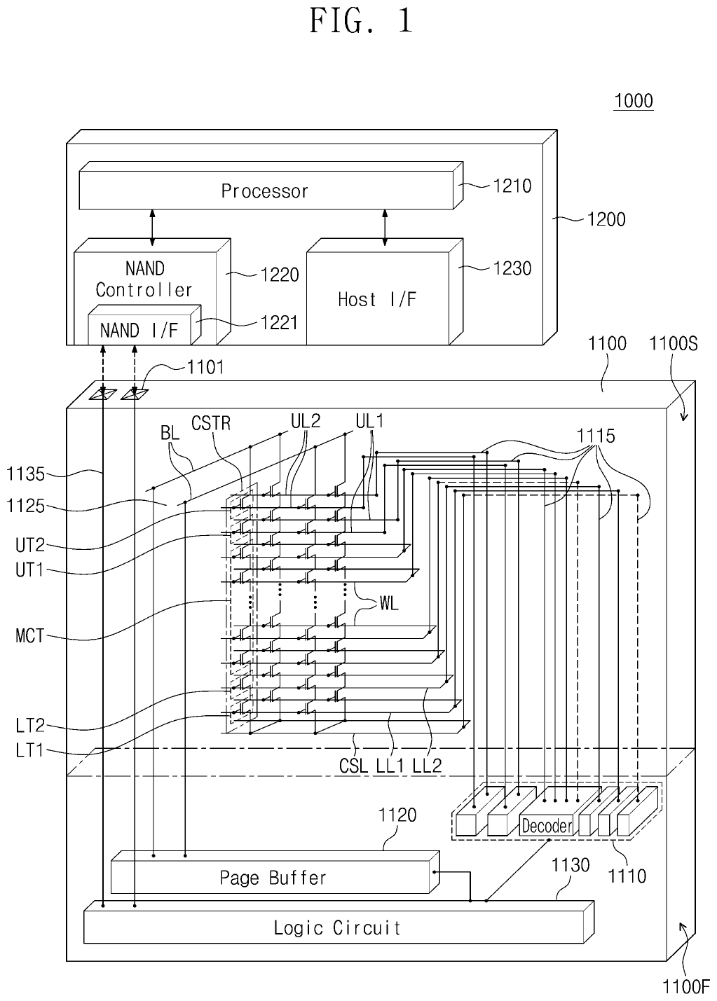

FIG. 1 is a diagram schematically illustrating an electronic system including a semiconductor device according to an embodiment of the inventive concept. Referring to FIG. 1, an electronic system 1000 may include a semiconductor device 1100 and a controller 1200, which may be electrically connected to the semiconductor device 1100. The electronic system 1000 may be a storage device, which may include one or more semiconductor devices 1100, or the electronic system 100 may be an electronic device, which includes the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. The first structure 1100F may be provided or arranged beside or adjacent to the second structure 1100S. The first structure 1100F may include a peripheral circuit structure including a decoder circuit 1110, a page buffer 1120, and a logic circuit 1130. The second structure 1100S may be a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of the lower transistors LT1 and LT2 and the number of the upper transistors UT1 and UT2 may be variously changed, according to embodiments.

The upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

The lower transistors LT1 and LT2 may include a lower erase control transistor LT1 and a ground selection transistor LT2, which may be connected in series. The upper transistors UT1 and UT2 may include a string selection transistor UT1 and an upper erase control transistor UT2, which may be connected in series. At least one of the lower and upper erase control transistors LT1 and UT1 may be used to perform an erase operation, in which a gate-induced drain leakage (GIDL) phenomenon is used to erase data stored in the memory cell transistors MCT.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer 1120 through second connection lines 1125, which are extended from the first structure 1100F into the second structure 1100S.

In the first structure 1100F, the decoder circuit 1110 and the page buffer 1120 may be configured to control a control operation, which may be performed on at least one of the memory cell transistors MCT by a selection memory cell transistor. The decoder circuit 1110 and the page buffer 1120 may be controlled by the logic circuit 1130. The electronic system 1000 may communicate with the controller 1200 through an input/output pad 1101 electrically connected to the logic circuit 1130. The input/output pad 1101 may be electrically connected to the logic circuit 1130 through an input/output connection line 1135, which is extended from the first structure 1100F into the second structure 1100S.

The controller 1200 may include a processor 1210, a NAND controller 1220, and a host interface 1230. In some embodiments, the electronic system 1000 may include a plurality of semiconductor devices 1100, and in this case, the controller 1200 may control the electronic systems 1000.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221, which may be used to communicate with the semiconductor device 1100. The NAND interface 1221 may be used to transmit and receive control commands to control the semiconductor device 1100, data to be written in and/or read from the memory cell transistors MCT of the semiconductor device 1100, and so forth. The host interface 1230 may be configured to allow for communication between the electronic system 1000 and an external host. When a control command is received from a host through the host interface 1230, the processor 1210 may control the semiconductor device 1100 in response to the control command.

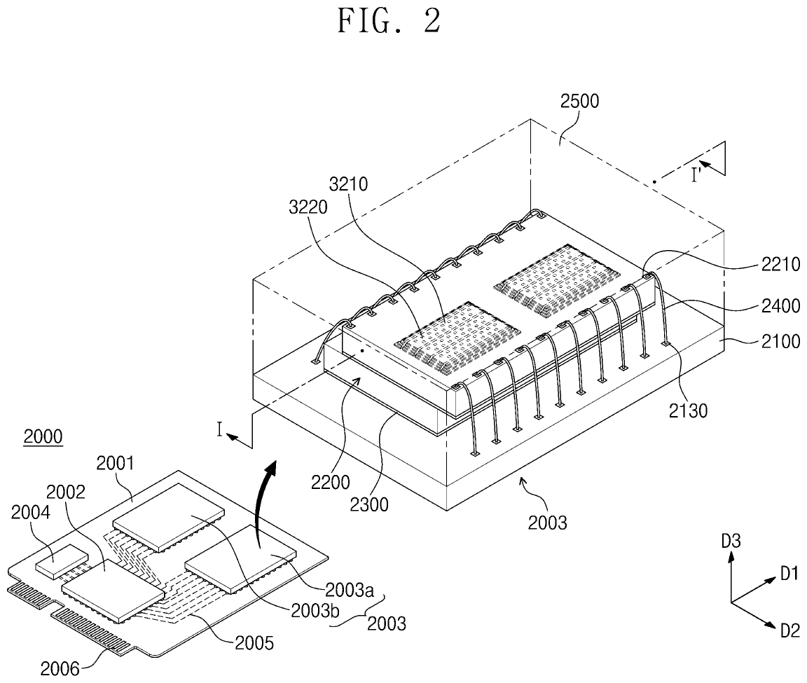

FIG. 2 is a perspective view schematically illustrating an electronic system including a semiconductor device according to some embodiments of the inventive concepts. Referring to FIG. 2, an electronic system 2000 may include a main substrate 2001 and a controller 2002, at least one semiconductor package 2003, and a DRAM 2004, which may be mounted on the main substrate 2001. The semiconductor package 2003 and the DRAM 2004 may be connected to the controller 2002 and to each other by interconnection patterns 2005, which may be formed in the main substrate 2001.

The main substrate 2001 may include a connector 2006, which includes a plurality of pins coupled to an external host. In the connector 2006, the number and arrangement of the pins may depend on a communication interface between the electronic system 2000 and the external host. In some embodiments, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In some embodiments, the electronic system 2000 may be driven by power (e.g., a power signal), which may be supplied from the external host through the connector 2006. The electronic system 2000 may further include a power management integrated circuit (PMIC) that distributes or is configured to distribute power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which may relieve or reduce technical difficulties caused by a difference in speed between the semiconductor package 2003, which serves as a data storage device, and an external host. In some embodiments, the DRAM 2004 in the electronic system 2000 may serve as a cache memory and may provide a storage space that temporarily stores data during a control operation on the semiconductor package 2003. In the case where the electronic system 2000 includes the DRAM 2004, the controller 2002 may further include a DRAM controller to control the DRAM 2004, in addition to a NAND controller to controlling the semiconductor package 2003.

The semiconductor package 2003 may include first and second semiconductor packages 2003a and 2003b, which may be spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 on respective bottom surfaces of the semiconductor chips 2200, a connection structure 2400 electrically connecting the semiconductor chips 2200 to the package substrate 2100, and a molding layer 2500 on the package substrate 2100 to cover the semiconductor chips 2200 and the connection structure 2400.

The package substrate 2100 may be a printed circuit board including package upper pads 2130. Each of the semiconductor chips 2200 may include an input/output pad 2210. The input/output pad 2210 may correspond to the input/output pad 1101 of FIG. 1. Each of the semiconductor chips 2200 may include gate stacks 3210 and vertical structures 3220. Each of the semiconductor chips 2200 may include a semiconductor device, which will be described below, according to some embodiments of the inventive concepts.

The connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. In each of the first and second semiconductor packages 2003a and 2003b, the semiconductor chips 2200 may be electrically connected to each other by a connection structure including penetration electrodes (e.g., through silicon vias (TSVs)), not by the connection structure 2400 provided in the form of bonding wires.

The controller 2002 and the semiconductor chips 2200 may be included in a single package. The controller 2002 and the semiconductor chips 2200 may be mounted on a separate interposer substrate, which is prepared regardless of the main substrate 2001, and may be connected to each other through interconnection lines, which are provided in the interposer substrate.

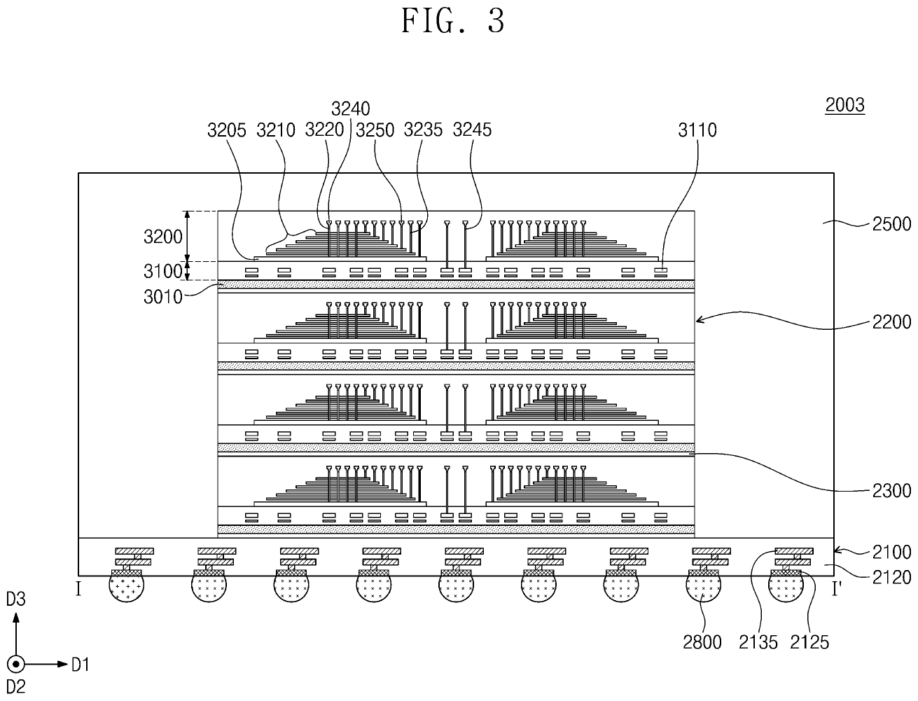

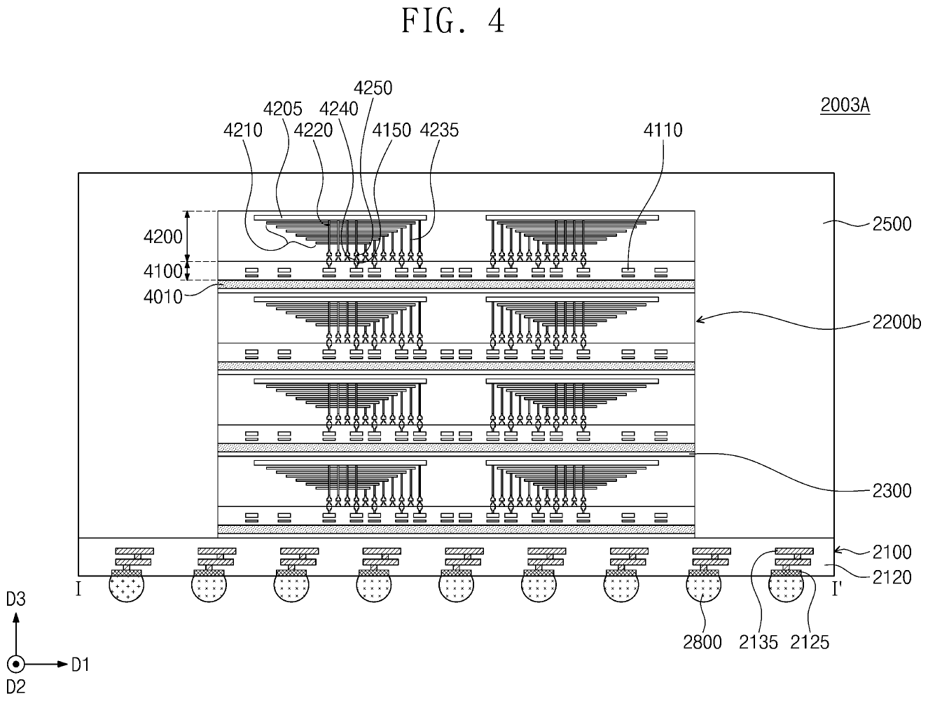

FIGS. 3 and 4 are sectional views, each of which schematically illustrates a semiconductor package according to some embodiments of the inventive concepts. For example, FIGS. 3 and 4 are sectional views, which are taken along a line I-I′ of FIG. 2, and illustrate two different examples of the semiconductor package of FIG. 2. Referring to FIG. 3, in the semiconductor package 2003, the package substrate 2100 may be a printed circuit board. The package substrate 2100 may include a package substrate body portion 2120, the package upper pads 2130 (e.g., of FIG. 2), which may be on a top surface of the package substrate body portion 2120, lower pads 2125, which may be on or exposed through a bottom surface of the package substrate body portion 2120, and internal lines 2135, which are provided in the package substrate body portion 2120 to electrically connect the package upper pads 2130 to the lower pads 2125. The package upper pads 2130 may be electrically connected to the connection structures 2400. The lower pads 2125 may be connected to the interconnection patterns 2005, which may be provided in a main substrate 2001 of the electronic system 2000, through conductive connecting portions 2800, as shown in FIG. 2.

Each of the semiconductor chips 2200 may include a semiconductor substrate 3010 and first and second structures 3100 and 3200, which may be sequentially stacked on the semiconductor substrate 3010. The first structure 3100 may include a peripheral region, in which peripheral lines 3110 are provided. The second structure 3200 may include a source structure 3205, a stack 3210 on the source structure 3205, the vertical structures 3220 and separation structures 3230 penetrating the stack 3210, bit lines 3240 electrically connected to the vertical structures 3220, and cell contact plugs 3235 electrically connected to the word lines WL (e.g., of FIG. 1) of the stack 3210. Each of the first and second structures 3100 and 3200 and the semiconductor chips 2200 may further include separation structures to be described below.

Each of the semiconductor chips 2200 may include penetration lines 3245, which may be electrically connected to the peripheral lines 3110 of the first structure 3100 and may be extended into the second structure 3200. The penetration line 3245 may be outside the stack 3210, and in some embodiments, the penetration line 3245 may be provided to further penetrate the stack 3210. Each of the semiconductor chips 2200 may further include the input/output pad 2210 (e.g., see FIG. 2), which may be electrically connected to the peripheral lines 3110 of the first structure 3100.

Referring to FIG. 4, in a semiconductor package 2003A, each of semiconductor chips 2200a may include a semiconductor substrate 4010, a first structure 4100 on the semiconductor substrate 4010, and a second structure 4200, which may be provided on the first structure 4100 and may be bonded with the first structure 4100 in a wafer bonding manner.

The first structure 4100 may include a peripheral region, in which a peripheral line 4110 and first junction structures 4150 are provided. The second structure 4200 may include a source structure 4205, a stack 4210 between the source structure 4205 and the first structure 4100, vertical structures 4220 and a separation structure 4230 penetrating the stack 4210, and second junction structures 4250, which are respectively and electrically connected to the vertical structures 4220 and the word lines WL (e.g., of FIG. 1) of the stack 4210. For example, the second junction structures 4250 may be electrically and respectively connected to the vertical structures 4220 and the word lines WL through bit lines 4240, which are electrically connected to the vertical structures 4220, and cell contact plugs 4235, which are electrically connected to the word lines WL. The first junction structures 4150 of the first structure 4100 may be in contact with and coupled to the second junction structures 4250 of the second structure 4200. The junction portions of the first and second junction structures 4150 and 4250 may be formed of or include, for example, copper (Cu).

Each of the first and second structures 4100 and 4200 and the semiconductor chips 2200a may further include a source structure to be described below. Each of the semiconductor chips 2200a may further include the input/output pads 2210 (e.g., of FIG. 2), which are electrically connected to the peripheral lines 4110 of the first structure 4100.

The semiconductor chips 2200 or 2200a of FIG. 3 or 4 may be electrically connected to each other by the connection structures 2400, which are provided in the form of bonding wires. However, in some embodiments, semiconductor chips, which are provided in the same semiconductor package as the semiconductor chips 2200 or 2200a of FIG. 3 or 4, may be electrically connected to each other by a connection structure including through silicon vias (TSVs).

The first structure 3100 or 4100 of FIG. 3 or 4 may correspond to a peripheral circuit structure in some embodiments to be described below, and the second structure 3200 or 4200 of FIG. 3 or 4 may correspond to a cell array structure in some embodiments to be described below.

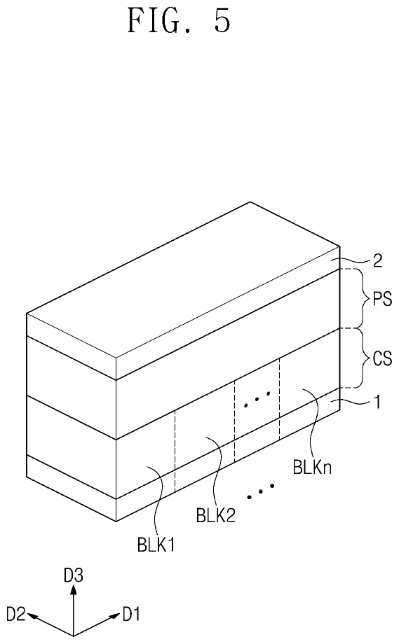

FIG. 5 is a perspective view schematically illustrating a semiconductor device according to some embodiments of the inventive concepts. Referring to FIG. 5, a three-dimensional semiconductor device may include a peripheral circuit structure PS and a cell array structure CS, and here, the peripheral circuit structure PS may be stacked on the cell array structure CS. That is, the cell array structure CS and the peripheral circuit structure PS may be overlapped with each other, when viewed in a plan view. The cell array structure CS and the peripheral circuit structure PS may be integrated on a first substrate 1 and a second substrate 2, respectively, and the peripheral circuit structure PS on the second substrate 2 may be stacked on the cell array structure CS on the first substrate 1 to be in contact with the cell array structure CS.

The cell array structure CS may include a cell array including a plurality of memory cells, which are three-dimensionally arranged. The cell array may be integrated on the first substrate 1. The cell array structure CS may include one or more mats, and each of the mats may include a plurality of memory blocks BLK0 to BLKn. Each of the memory blocks BLK0 to BLKn may include memory cells which are three-dimensionally arranged. For example, each of the memory blocks BLK0 to BLKn may include elements, which may be stacked on the first substrate 1 in a third direction D3.

The peripheral circuit structure PS may include peripheral circuits (e.g., row and column decoders, a page buffer, and a control circuit) which may be used to control the cell array. The peripheral circuits constituting the peripheral circuit structure PS may be integrated on a surface of the second substrate 2.

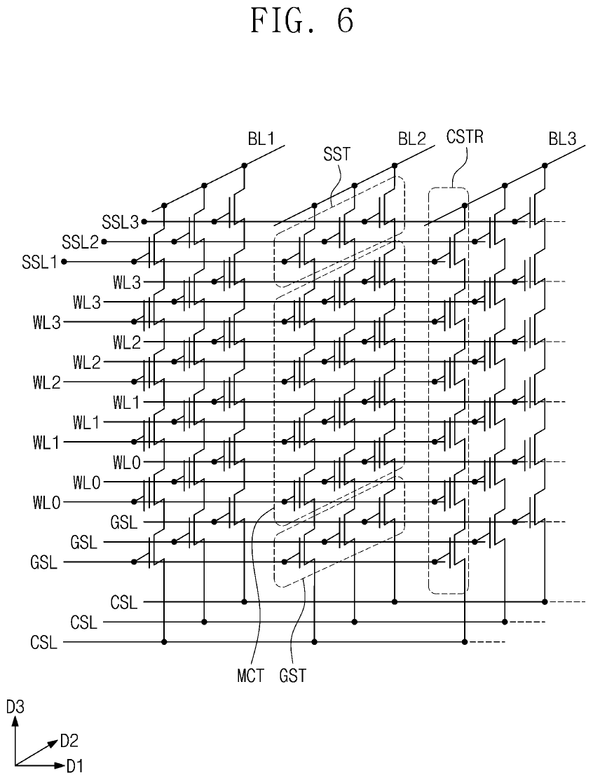

FIG. 6 is a circuit diagram illustrating a cell array of a semiconductor device according to some embodiments of the inventive concepts. Referring to FIG. 6, a three-dimensional semiconductor device may be a three-dimensional NAND FLASH memory device. The cell array of the three-dimensional NAND FLASH memory device may include the common source line CSL, a plurality of bit lines BL1 to BL3, and the cell strings CSTR between the common source line CSL and the bit lines BL1 to BL3. The cell strings CSTR may be extended in the third direction D3, which is perpendicular to first and second directions D1 and D2.

The bit lines BL1 to BL3 may be two-dimensionally arranged and the cell strings CSTR may be connected to each of the bit lines BL1 to BL3 in parallel. The cell strings CSTR may be connected in common to the common source line CSL. That is, the cell strings CSTR may be between the bit lines BL1 to BL3 and the common source line CSL. A plurality of the common source lines CSL may be two-dimensionally arranged. Here, the common source lines CSL may be applied with the same voltage or each of the common source lines CSL may be electrically controlled.

Each of the cell strings CSTR may be composed of a ground selection transistor GST, which may be coupled to the common source line CSL, a string selection transistor SST, which may be coupled to one of the bit lines BL1 to BL3, and the memory cell transistors MCT, which may be between the ground and string selection transistors GST and SST. The ground selection transistor GST, the string selection transistor SST, and the memory cell transistors MCT may be connected in series. The common source line CSL may be connected in common to the source regions of the ground selection transistors GST.

A ground selection line GSL, a plurality of word lines WL0 to WL3, and a plurality of string selection lines SSL1 to SSL3, which may be between the common source line CSL and the bit lines BL1 to BL3, may be used the gate electrodes of the ground selection transistor GST, the memory cell transistors MCT, and the string selection transistors SST, respectively. In addition, each of the memory cell transistors MCT may include a data storing element.

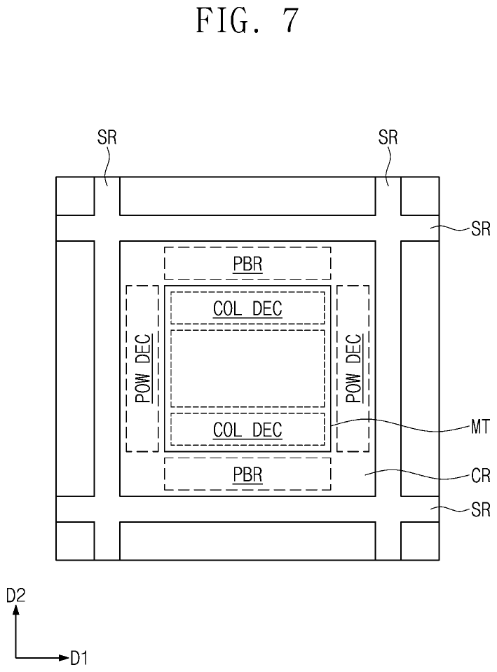

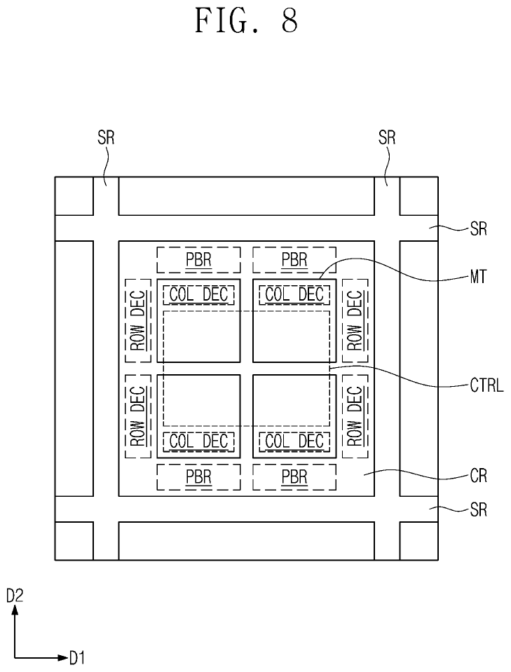

FIGS. 7 and 8 are schematic plan views, each of which illustrates a semiconductor device according to some embodiments of the inventive concepts. Referring to FIGS. 7 and 8 and also with reference to FIG. 5, chip regions CR of the second substrate 2 including the peripheral circuit structure PS may be respectively on chip regions CR of the first substrate 1 including the cell array structure CS.

Row and column decoders ROW DEC and COL DEC, a page buffer PBR, and control circuits CTRL constituting the peripheral circuit structure PS may be in each of the chip regions CR and on a surface of the second substrate 2. Here, the chip regions CR may be enclosed by a scribe line region SR, and here, a sawing step of the fabrication process will be performed on the scribe line region SR to separate three-dimensional semiconductor devices in the chip regions CR from each other.

Referring to FIG. 7, one mat MT or one block constituting the cell array structure may be provided in each chip region CR. The mat MT may be provided on the first substrate 1 of FIG. 5. The mat MT may be overlapped with a portion of the peripheral circuit structure PS of FIG. 5. In some embodiments, the row decoders ROW DEC and the page buffers PBR may be arranged around the mat MT, when viewed in a plan view. The column decoders COL DEC and the control circuit CTRL may be overlapped with the mat MT. In some embodiments, the peripheral circuits constituting the peripheral circuit structure PS of FIG. 5 may be freely disposed on the mat MT.

Referring to FIG. 8, a plurality of mats MT or a plurality of blocks constituting the cell array structure CS of FIG. 5 may be provided in each chip region CR. The mats MT may be arranged in the first and second directions D1 and D2. The mats MT may be provided on the first substrate 1 of FIG. 5.

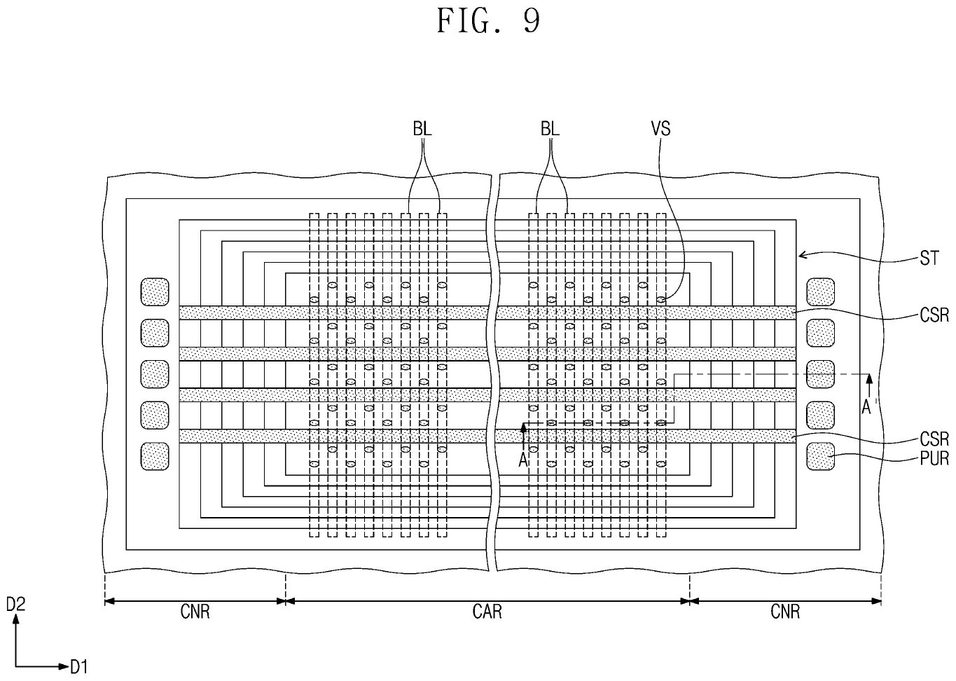

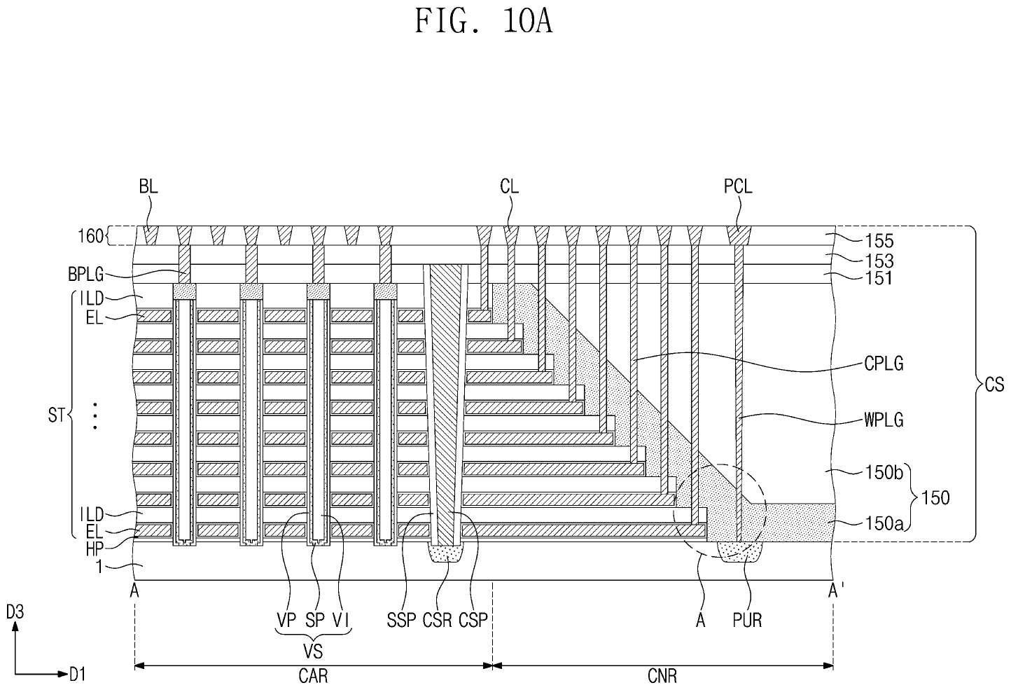

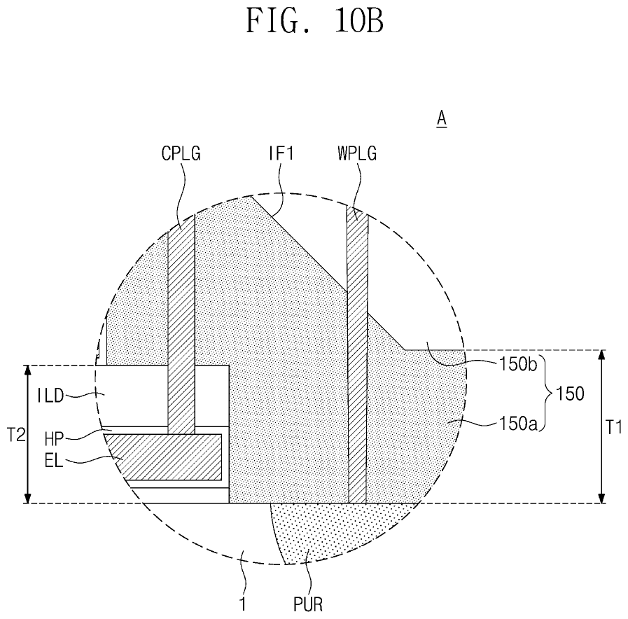

FIG. 9 is a plan view illustrating a semiconductor device according to some embodiments of the inventive concept. FIG. 10A is a sectional view, which is taken along a line A-A′ of FIG. 9 to illustrate a semiconductor device according to some embodiments of the inventive concept. FIG. 10B is an enlarged sectional view illustrating a portion ‘A’ of FIG. 10A. Referring to FIGS. 9, 10A, and 10B, the first substrate 1 may be provided. The first substrate 1 may be formed of or include at least one of semiconductor materials and may be a silicon wafer, a silicon-germanium wafer, a germanium wafer, or a single-crystalline epitaxial layer grown on a single-crystalline silicon wafer. As an example, the first substrate 1 may be a silicon wafer. In addition, the first substrate 1 may be formed of or include a semiconductor material, which is doped with dopants of a first conductivity type (e.g., p-type), or an undoped or intrinsic semiconductor material. The first substrate 1 may have one of single crystalline, amorphous, and polycrystalline structures. The first substrate 1 may include a cell array region CAR and a connection region CNR around the cell array region CAR. Hereinafter, as shown in FIG. 10A, the connection region CNR will be described as being placed near the cell array region CAR in the first direction D1, for convenience in description. However, the inventive concept is not limited to this example, and as described above, the connection region CNR may enclose the cell array region CAR, when viewed in a plan view.

The cell array structure CS may be provided on the first substrate 1 and may include stacks ST, vertical structures VS, and interconnection structures CPLG, CL, WPLG, and PCL.

The stacks ST may be extended on the first substrate 1 in the first direction D1 and may be spaced apart from each other in the second direction D2. Each of the stacks ST may include electrodes EL, which are vertically stacked on the first substrate 1, and insulating layers ILD, which are interposed between the electrodes EL. In the stacks ST, a thickness of each of the insulating layers ILD may be changed, depending on technical requirements for the semiconductor memory device. In some embodiments, some of the insulating layers ILD may be formed to be thicker than the others. The insulating layers ILD may be formed of or include silicon oxide (SiO). The electrodes EL may be formed of or include at least one of conductive materials and may be a multiple layer including at least one of a semiconductor layer, a metal silicide layer, a metal layer, or a metal nitride layer, or combinations of two or more thereof.

The stacks ST may be extended from the cell array region CAR to the connection region CNR in the first direction D1 and may have a stepwise structure in the connection region CNR. Lengths of the electrodes EL of the stacks ST in the first direction D1 may decrease as a distance from the first substrate 1 increases. The stacks ST may have a staircase structure of various shapes, in the connection region CNR.

The semiconductor device may be a three-dimensional NAND FLASH memory device and the cell strings CSTR of FIG. 6 may be integrated on the first substrate 1. In this case, the lowermost and uppermost ones of the electrodes EL in the stacks ST may be used as the gate electrodes of the selection transistors SST and GST of FIG. 6. For example, the uppermost electrode EL may be used as the gate electrode of the string selection transistor SST (e.g., see FIG. 6) that controls the electric connection between the bit line BL and the vertical structures VS, and the lowermost electrode EL may be used as the gate electrode of the ground selection transistor GST (e.g., see of FIG. 6) that controls the electric connection between the common source line CSL of FIG. 6 and the vertical structures VS. In addition, the electrodes EL between the uppermost and lowermost ones of the electrodes EL may be used as the control gate electrodes of the memory cells and as the word lines WL0-WL3 (e.g., see FIG. 6) connecting them to each other.

In the cell array region CAR, the vertical structures VS may be provided to penetrate the stacks ST and be in contact with the first substrate 1. The vertical structures VS may be electrically connected to the first substrate 1. The vertical structures VS may be arranged in a specific direction or in a zigzag shape, when viewed in a plan view. Moreover, in the connection region CNR, dummy vertical structures may be provided which may have substantially the same structure as the vertical structures VS.

The vertical structures VS may be formed of or include a semiconductor material (e.g., silicon (Si) or germanium (Ge)). Furthermore, the vertical structures VS may be formed of or include a semiconductor material, which may be doped with dopants, or an undoped or intrinsic semiconductor material. The vertical structures VS containing the semiconductor material may be used as channel regions of the selection transistors SST and GST and the memory cell transistors MCT described with reference to FIG. 5. Bottom surfaces of the vertical structures VS may be located between top and bottom surfaces of the first substrate 1. A contact pad may be provided on the vertical structure VS or in an upper portion of the vertical structure VS and may be coupled to a bit line contact plug BPLG. Each of the vertical structures VS may include a semiconductor pattern SP and a vertical insulating pattern VP, which may be in contact with the first substrate 1. The semiconductor pattern SP may have a hollow pipe shape or a macaroni shape. The semiconductor pattern SP may have a closed bottom portion, and an inner space of the semiconductor pattern SP may be filled with a gapfill insulating pattern VI. The semiconductor pattern SP may be in contact with atop surface of the first substrate 1. The semiconductor pattern SP may be in an undoped state or may be doped with dopants, which have the same conductivity type as the first substrate 1. The semiconductor pattern SP may have a poly-crystalline or single-crystalline structure.

The vertical insulating pattern VP may be between the stack ST and the vertical structures VS. The vertical insulating pattern VP may be extended in the third direction D3 to surround a side surface of the vertical structure VS. In other words, the vertical insulating pattern VP may be shaped like a pipe or macaroni with open top and bottom. The vertical insulating pattern VP may include one or more layers. The vertical insulating pattern VP may be a portion of a data storing layer. For example, the vertical insulating pattern VP may include a tunnel insulating layer, a charge storing layer, and a blocking insulating layer, which may be used as a data storing layer DS of a NAND FLASH memory device. For example, the charge storing layer may be a trap insulating layer, a floating gate electrode, or an insulating layer including conductive nanodots. In greater detail, the charge storing layer may include at least one of a silicon nitride layer, a silicon oxynitride layer, a silicon-rich nitride layer, a nanocrystalline silicon layer, or a laminated trap layer. The tunnel insulating layer may be formed of at least one of materials, whose band gaps are greater than that of the charge storing layer, and the blocking insulating layer may be formed of or include high-k dielectric materials (e.g., aluminum oxide (Al₂O₃) and hafnium oxide (Hf₂O)). In some embodiments, the vertical insulating layer may include at least one layer (not shown) exhibiting a phase-changeable property or a variable resistance property.

A horizontal insulating pattern HP may be provided between side surfaces of the electrodes EL and the vertical insulating pattern VP. The horizontal insulating pattern HP may be extended from the side surfaces of the electrodes EL to cover the top and bottom surfaces of the electrodes EL. The horizontal insulating pattern HP may be used as a part of the data storing layer DS of a NAND FLASH memory device and may include a charge storing layer and a blocking insulating layer. Alternatively, the horizontal insulating pattern HP may include the blocking insulating layer.

Common source regions CSR may be between adjacent ones of the stacks ST and in the first substrate 1. The common source regions CSR may be extended in the first direction D1 to be parallel to the stacks ST. The common source regions CSR may be formed by doping the first substrate 1 with dopants of a second conductivity type. The common source regions CSR may include n-type dopants (e.g., arsenic (As) or phosphorus (P)).

A common source plug CSP may be coupled to the common source region CSR. A side insulating spacer SSP may be interposed between the common source plug CSP and the stacks ST. During a reading or programming operation of the three-dimensional NAND FLASH memory device, a ground voltage may be applied to the common source region CSR through the common source plug CSP.

A first insulating gapfill layer 150 may be on the first substrate 1 and may cover end portions of the electrodes EL having a stepwise structure. A top surface of the first insulating gapfill layer 150 may be coplanar with a top surface of the stack ST. That is, the first insulating gapfill layer 150 may be a planarization insulating layer, which is provided on the stack ST. The first insulating gapfill layer 150 may include a first insulating layer 150a and a second insulating layer 150b.

The first insulating layer 150a may be on the first substrate 1. In the connection region CNR, the first insulating layer 150a may cover the stepwise structure of the stack ST. In greater detail, the first insulating layer 150a may cover the stack ST and the top surface of the first substrate 1. The first insulating layer 150a may be in contact with the stepwise structure of the stack ST and the top surface of the first substrate 1. Here, the first insulating layer 150a may be in close contact with the stack ST and the first substrate 1. For example, an interfacial defect (e.g., an air gap, an air void, or an impurity) may not exist between the first insulating layer 150a and the stack ST and between the first insulating layer 150a and the first substrate 1. This will be described in greater detail, when a method of fabricating a semiconductor device will be described below. A first thickness T1 of the first insulating layer 150a may be larger than a second thickness T2 of one stepped portion of the stepwise structure of the stack ST. A top surface of the first insulating layer 150a may be coplanar with the top surface of the stack ST.

The second insulating layer 150b may be on the first insulating layer 150a. The second insulating layer 150b may cover the first insulating layer 150a. The second insulating layer 150b may be spaced apart from the first substrate 1 and the stack ST by the first insulating layer 150a. A top surface of the second insulating layer 150b may be coplanar with the top surface of the first insulating layer 150a and the top surface of the stack ST.

A first interface IF1 between the first and second insulating layers 150a and 150b may be visible or observable. The first interface IF1 between the first and second insulating layers 150a and 150b may be spaced apart from the first substrate 1 and the stack ST. The first interface IF1 between the first and second insulating layers 150a and 150b may be flat. As shown in FIGS. 10A and 10B, the first interface IF1 between the first and second insulating layers 150a and 150b may be located on the stack ST and on a plane extending along the stepwise structure of the stack ST. The first interface IF1 between the first and second insulating layers 150a and 150b may be located at a side of the stack ST and on a plane extending along the top surface of the first substrate 1.

The first and second insulating layers 150a and 150b may be formed of or include different materials from each other. A first density of the first insulating layer 150a may be higher than a second density of the second insulating layer 150b. The uniformity of the first insulating layer 150a may be higher than the uniformity of the second insulating layer 150b. In the present specification, the expression “uniformity of a layer is high” may mean that the material constituting the layer is highly crystallized. For example, a defect (e.g., a crystal defect or impurity) in the first insulating layer 150a may be smaller than that in the second insulating layer 150b. Here, the impurity may refer to an element, which is not included in elements for a desired chemical structure of a layer or is different from dopants intended. The first insulating layer 150a may be formed of or include high-density plasma (HDP) oxide, as an example. Alternatively, the first insulating layer 150a may be formed of or include silica glass. The second insulating layer 150b may be formed of or include tetraethyl orthosilicate (TEOS) oxide, as an example.

The first and second insulating layers 150a and 150b may be doped with different dopants from each other. The first dopants in the first insulating layer 150a may be used to reduce a first etch rate of the first insulating layer 150a. In the case where the first insulating layer 150a includes high-density plasma (HDP) oxide, the first dopants in the first insulating layer 150a may include boron (B), phosphorus (P), carbon (C), nitrogen (N), or silicon (Si). In the case where the first insulating layer 150a includes silica glass, the first dopants in the first insulating layer 150a may include boron (B), phosphorus (P), or both of them. However, the inventive concept is not limited to this example, and the first dopants may contain other dopants, which may be provided in the first insulating layer 150a to adjust the first etch rate of the first insulating layer 150a. Second dopants in the second insulating layer 150b may contain boron (B), phosphorus (P), carbon (C), nitrogen (N), or silicon (Si). The first dopants in the first insulating layer 150a may be a material different from the second dopants in the second insulating layer 150b. Alternatively, the first dopants in the first insulating layer 150a may be the same material as the second dopants in the second insulating layer 150b. The first etch rate of the first insulating layer 150a may be equal or similar to a second etch rate of the second insulating layer 150b. This will be described in greater detail with reference to a fabrication method of a semiconductor device.

According to some embodiments of the inventive concepts, a portion of the first insulating gapfill layer 150 in contact with the stack ST may be provided as the first insulating layer 150a having a high density and a high uniformity. Due to the shape of the stack ST or the distortion or expansion of the stack ST, a stress may be exerted on the first insulating gapfill layer 150, but the first insulating layer 150a may not be damaged by the stress (or damaged less by the stress). That is, the first insulating layer 150a may prevent the first insulating gapfill layer 150 from being damaged by the stack ST, and thus, it may be possible to improve the structural stability of the semiconductor device. Furthermore, the first insulating layer 150a may be in close contact with the stack ST. That is, there may be no interfacial defect or void between the first insulating layer 150a and the stack ST. Thus, it may be possible to prevent a dislocation issue from occurring in the first insulating layer 150a by the interfacial defect or void and to improve the structural stability of the semiconductor device.

Referring further to FIGS. 9, 10A, and 10B, a first interlayer insulating layer 151 may cover the stack ST and the first insulating gapfill layer 150. The first interlayer insulating layer 151 may cover the vertical structures VS. The first interlayer insulating layer 151 may be provided on the first insulating gapfill layer 150 and may enclose the common source plug CSP. The common source plug CSP may be exposed to the outside of the first interlayer insulating layer 151 near a top surface of the first interlayer insulating layer 151. A second interlayer insulating layer 153 may cover the first interlayer insulating layer 151. The second interlayer insulating layer 153 may be provided on the first interlayer insulating layer 151 and may cover the common source plug CSP.

Bit lines BL may be on the second interlayer insulating layer 153 and may cross the stacks ST and extend in the second direction D2. The bit lines BL may be electrically connected to the vertical structure VS through the bit line contact plug BPLG. The bit lines BL may correspond to pads for the electric connection with the peripheral circuit structure.

An interconnection structure may be provided on the stepwise end portions of the stacks ST and may electrically connect the cell array structure CS to the peripheral circuit structure. The interconnection structure may include cell contact plugs CPLG, which may be provided to penetrate the first insulating gapfill layer 150 and the first and second interlayer insulating layers 151 and 153, and are respectively coupled to the end portions of the electrodes EL. The interconnection structure may include connection lines CL, which are provided on the second interlayer insulating layer 153 and are respectively coupled to the cell contact plugs CPLG. Furthermore, the interconnection structure may include well contact plugs WPLG, which are coupled to well pick-up regions PUR in the first substrate 1, and peripheral connection lines PCL, which are connected to the well contact plugs WPLG.

The well pick-up regions PUR may be in the first substrate 1 and may be adjacent to opposite end portions of each of the stacks ST. The well pick-up regions PUR may have the same conductivity type as the first substrate 1, and a doping concentration of the well pick-up regions PUR may be higher than a doping concentration of the first substrate 1. For example, the well pick-up regions PUR may contain p-type dopants (e.g., boron (B)) of high concentration. In some embodiments, during an erase operation of the three-dimensional NAND FLASH memory device, an erase voltage may be applied to the well pick-up regions PUR through the well contact plug WPLG.

A third interlayer insulating layer 155 may be provided on the second interlayer insulating layer 153 and may enclose the bit lines BL, the connection lines CL, and the peripheral connection lines PCL. Top surfaces of the bit lines BL, top surfaces of the connection lines CL, and top surfaces of the peripheral connection lines PCL may be exposed to the outside of the third interlayer insulating layer 155. The bit lines BL, the connection lines CL, and the peripheral connection lines PCL may constitute a cell array interconnection layer 160. The bit lines BL, the connection lines CL, and the peripheral connection lines PCL may correspond to pads of the cell array structure CS, which may be electrically connected to the peripheral circuit structure.

In the following embodiments, some elements previously described with reference to FIGS. 9, 10A, and 10B may be identified by the same reference number without repeating an overlapping description thereof, for concise description. That is, technical features different from the embodiments of FIGS. 9, 10A, and 10B will be mainly mentioned in the following description of the present embodiment.

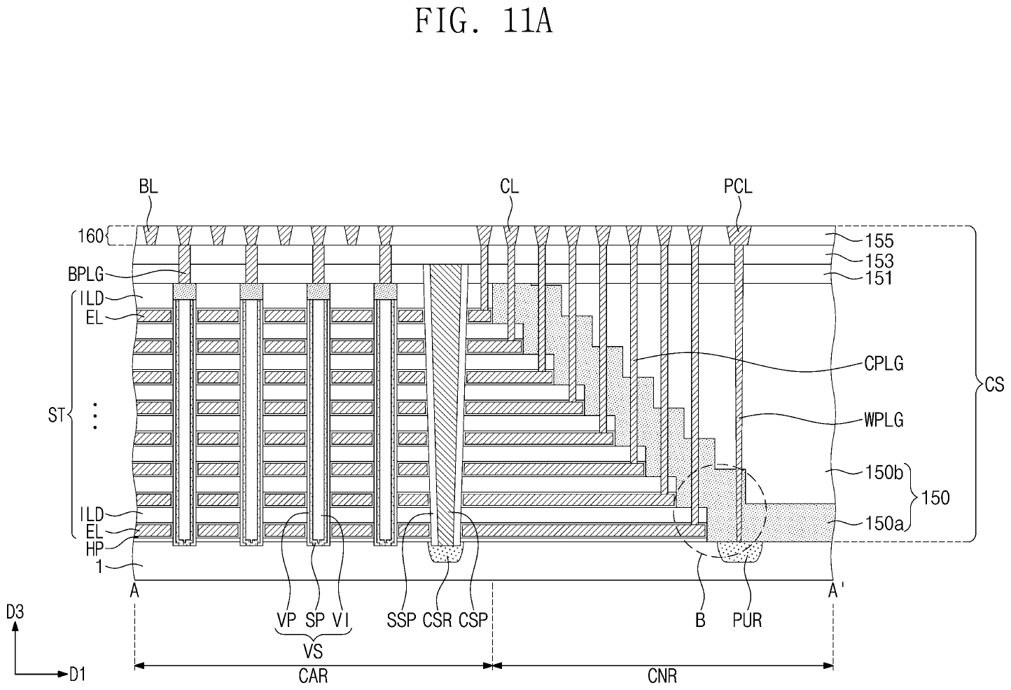

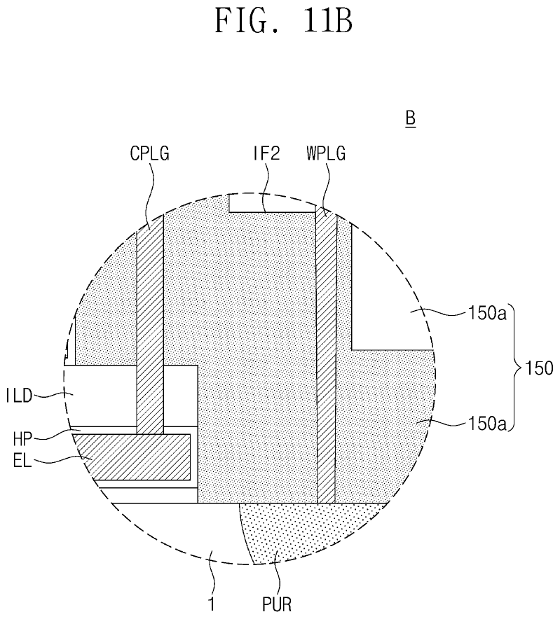

FIG. 11A is a sectional view, which is taken along a line A-A′ of FIG. 9 to illustrate a semiconductor device according to an embodiment of the inventive concept. FIG. 11B is an enlarged sectional view illustrating a portion ‘B’ of FIG. 11A. Referring to FIGS. 9, 11A, and 11B, the first insulating gapfill layer 150 may be on the first substrate 1 and may cover the end portions of the electrodes EL having the stepwise structure. The first insulating gapfill layer 150 may include the first insulating layer 150a and the second insulating layer 150b.

The first insulating layer 150a may be on the first substrate 1. In the connection region CNR, the first insulating layer 150a may cover the stepwise structure of the stack ST. In greater detail, the first insulating layer 150a may cover and conform to the stack ST and the top surface of the first substrate 1. In the present specification, the expression “a layer conformally covers a structure” means that the layer has a shape corresponding to a surface profile of the structure or has the same or similar surface shape as that of the structure. The first insulating layer 150a may have a stepwise structure.

The second insulating layer 150b may be on the first insulating layer 150a. The second insulating layer 150b may cover the first insulating layer 150a. The second insulating layer 150b may be spaced apart from the first substrate 1 and the stack ST by the first insulating layer 150a.

Owing to the shape of the first insulating layer 150a, a second interface IF2 between the first and second insulating layers 150a and 150b may have a stepwise shape. As shown in FIGS. 11A and 11B, the second interface IF2 between the first and second insulating layers 150a and 150b may correspond to the stepwise structure of the stack ST, on the stack ST. The second interface IF2 between the first and second insulating layers 150a and 150b may be located at a side of the stack ST and on a plane extending along the top surface of the first substrate 1.

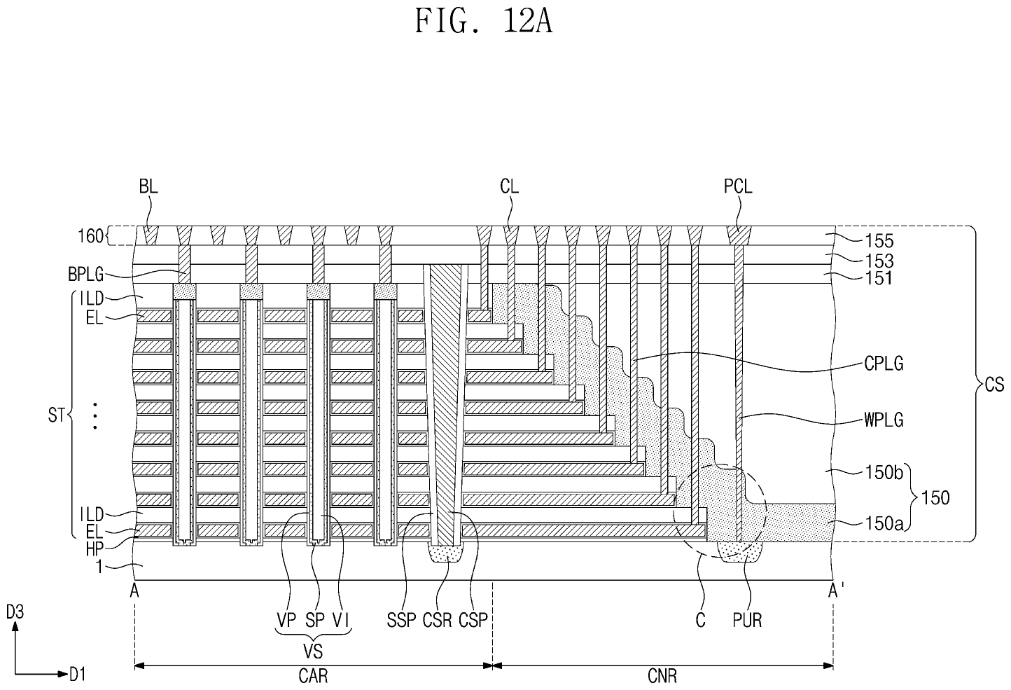

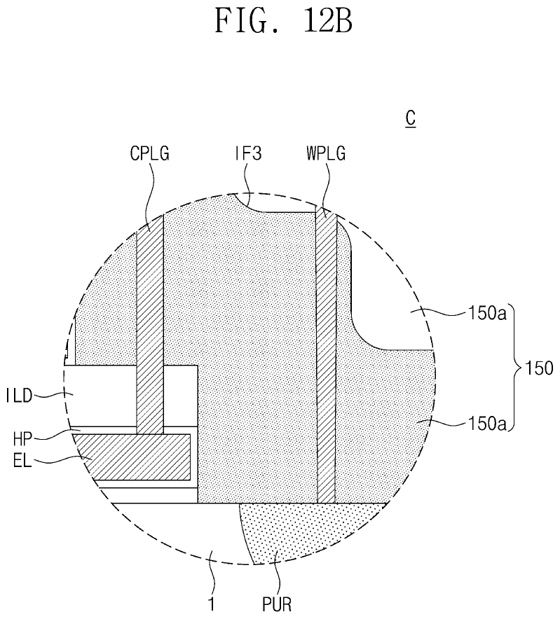

FIG. 12A is a sectional view, which is taken along the line A-A′ of FIG. 9 to illustrate a semiconductor device according to an embodiment of the inventive concept. FIG. 12B is an enlarged sectional view illustrating a portion ‘C’ of FIG. 12A. Referring to FIGS. 9, 12A, and 12B, the first insulating gapfill layer 150 may be on the first substrate 1 and may cover the end portions of the electrodes EL having the stepwise structure. The first insulating gapfill layer 150 may include the first insulating layer 150a and the second insulating layer 150b.

The first insulating layer 150a may be disposed on the first substrate 1. In the connection region CNR, the first insulating layer 150a may cover the stepwise structure of the stack ST. In more detail, the first insulating layer 150a may cover and conform to the stack ST and the top surface of the first substrate 1. Here, a surface of the first insulating layer 150a may have a wavy or undulating shape, unlike the embodiment of FIGS. 11A and 11B.

The second insulating layer 150b may be on the first insulating layer 150a. The second insulating layer 150b may cover the first insulating layer 150a. The second insulating layer 150b may be spaced apart from the first substrate 1 and the stack ST by the first insulating layer 150a.

A third interface IF3 between the first and second insulating layers 150a and 150b may have a wavy or undulating shape, owing to the shape of the first insulating layer 150a. Here, the wavy or undulating shape of the third interface IF3 may correspond to the stepwise structure of the stack ST. As shown in FIGS. 12A and 12B, the third interface IF3 between the first and second insulating layers 150a and 150b may have a structure, in which concave and convex portions curved in directions toward or away from the stack ST are repeatedly formed. The third interface IF3 between the first and second insulating layers 150a and 150b may be located at a side of the stack ST and on a plane extending along the top surface of the first substrate 1.

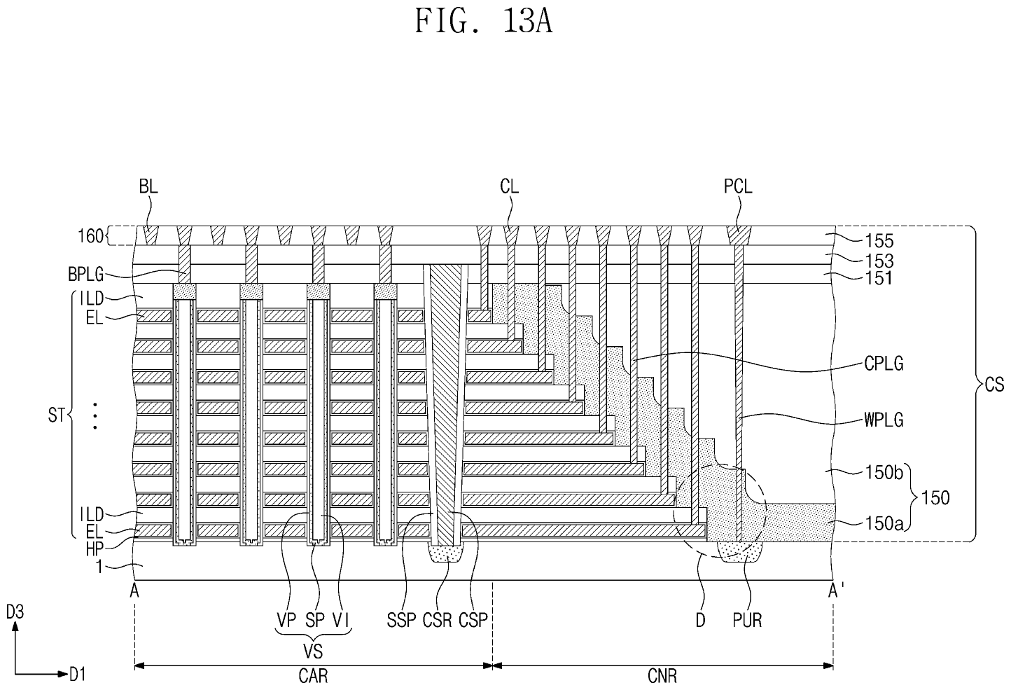

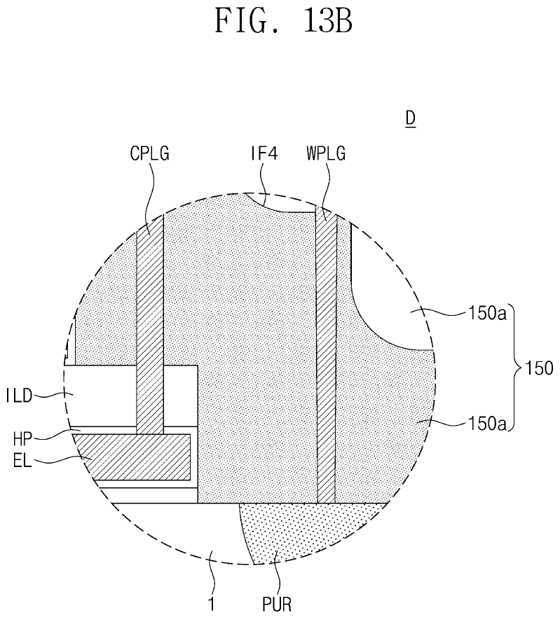

FIG. 13A is a sectional view, which is taken along the line A-A′ of FIG. 9 to illustrate a semiconductor device according to some embodiments of the inventive concept. FIG. 13B is an enlarged sectional view illustrating a portion ‘D’ of FIG. 13A. Referring to FIGS. 9, 13A, and 13B, the first insulating gapfill layer 150 may be on the first substrate 1 to cover the end portions of the electrodes EL having the stepwise structure. The first insulating gapfill layer 150 may include the first insulating layer 150a and the second insulating layer 150b.

The first insulating layer 150a may be on the first substrate 1. In the connection region CNR, the first insulating layer 150a may cover the stepwise structure of the stack ST. In greater detail, the first insulating layer 150a may cover and conform to the stack ST and the top surface of the first substrate 1. A surface of the first insulating layer 150a may have a wavy or undulating shape.

The second insulating layer 150b may be on the first insulating layer 150a. The second insulating layer 150b may cover the first insulating layer 150a. The second insulating layer 150b may be spaced apart from the first substrate 1 and the stack ST by the first insulating layer 150a.

A fourth interface IF4 between the first and second insulating layers 150a and 150b may have a wavy or undulating shape, owing to the shape of the first insulating layer 150a. Here, the wavy or undulating shape of the fourth interface IF4 may correspond to the stepwise structure of the stack ST. Here, unlike the embodiment of FIGS. 12A and 12B, the fourth interface IF4 between the first and second insulating layers 150a and 150b may have a structure, in which concave portions recessed in a direction toward the stack ST are repeatedly formed. The fourth interface IF4 between the first and second insulating layers 150a and 150b may be located at a side of the stack ST and on a plane extending along the top surface of the first substrate 1.

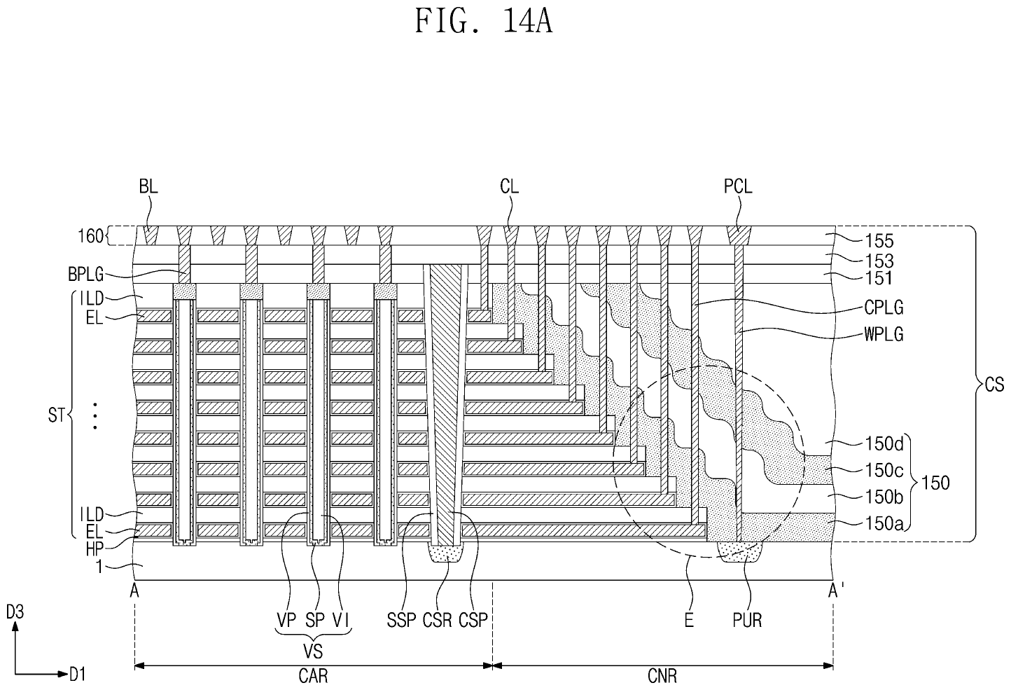

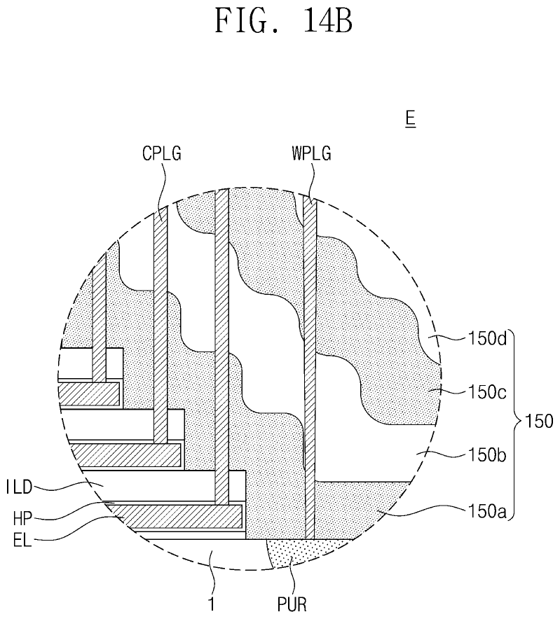

FIG. 14A is a sectional view, which is taken along the line A-A′ of FIG. 9 to illustrate a semiconductor device according to some embodiments of the inventive concepts. FIG. 14B is an enlarged sectional view illustrating a portion ‘E’ of FIG. 14A. Referring to FIGS. 9, 14A, and 14B, the first insulating gapfill layer 150 may be on the first substrate 1 and may cover the end portions of the electrodes EL having the stepwise structure. The first insulating gapfill layer 150 may include the first insulating layer 150a, the second insulating layer 150b, a third insulating layer 150c, and a fourth insulating layer 150d.

The first insulating layer 150a may be on the first substrate 1. In the connection region CNR, the first insulating layer 150a may cover the stepwise structure of the stack ST. The first insulating layer 150a may cover and conform to the stack ST and the top surface of the first substrate 1. The second insulating layer 150b may be on the first insulating layer 150a. The second insulating layer 150b may cover and conform to the first insulating layer 150a. The second insulating layer 150b may be spaced apart from the first substrate 1 and the stack ST by the first insulating layer 150a. The third insulating layer 150c may be on the second insulating layer 150b. The third insulating layer 150c may cover and conform to the second insulating layer 150b. The fourth insulating layer 150d may be on the third insulating layer 150c. The fourth insulating layer 150d may cover the third insulating layer 150c.

The interfaces between the first, second, third, and fourth insulating layers 150a, 150b, 150c, and 150d may have a wavy or undulating shape, owing to the shapes of the first, second, and third insulating layers 150a, 150b, and 150c. Here, the wavy or undulating shape of the interfaces between the first, second, third, and fourth insulating layers 150a, 150b, 150c, and 150d may correspond to the stepwise structure of the stack ST. As shown in FIGS. 14A and 14B, the interfaces between the first, second, third, and fourth insulating layers 150a, 150b, 150c, and 150d are illustrated to have a structure, in which concave and convex portions are repeatedly formed, but the inventive concept is not limited to this example. The interfaces between the first, second, third, and fourth insulating layers 150a, 150b, 150c, and 150d may have the same shape as the first interface IF1 described with reference to FIGS. 10A and 10B, the second interface IF2 described with reference to FIGS. 11A and 11B, the third interface IF3 described with reference to FIGS. 12A and 12B, or the fourth interface IF4 described with reference to FIGS. 13A and 13B.

The first and third insulating layers 150a and 150c may be formed of or include different materials from the second and fourth insulating layers 150b and 150d. A density of the first and third insulating layers 150a and 150c may be higher than a density of the second and fourth insulating layers 150b and 150d. The first and third insulating layers 150a and 150c may be provided to have uniformity higher than the second and fourth insulating layers 150b and 150d. The first and third insulating layers 150a and 150c may be formed of or include high-density plasma (HDP) oxide. In some embodiments, the first and third insulating layers 150a and 150c may be formed of or include silica glass. In some embodiments, the first and third insulating layers 150a and 150c may be formed of or include different materials, which may be chosen from the group consisting of high-density plasma (HDP) oxide and silica glass. The second and fourth insulating layers 150b and 150d may be formed of or include at least one of TEOS oxide materials.

The first and third insulating layers 150a and 150c may be doped with different dopants from the second and fourth insulating layers 150b and 150d. The dopants in the first and third insulating layers 150a and 150c may be provided to reduce an etch rate of the first and third insulating layers 150a and 150c. For example, in the case where the first and third insulating layers 150a and 150c include high-density plasma (HDP) oxide, the dopants in the first and third insulating layers 150a and 150c may contain boron (B), phosphorus (P), carbon (C), nitrogen (N), or silicon (Si). For example, in the case where the first and third insulating layers 150a and 150c include silica glass, the dopants in the first and third insulating layers 150a and 150c may contain boron (B), phosphorus (P), or both of boron and phosphorous. The dopants in the second and fourth insulating layers 150b and 150d may contain boron (B), phosphorus (P), carbon (C), nitrogen (N), or silicon (Si).

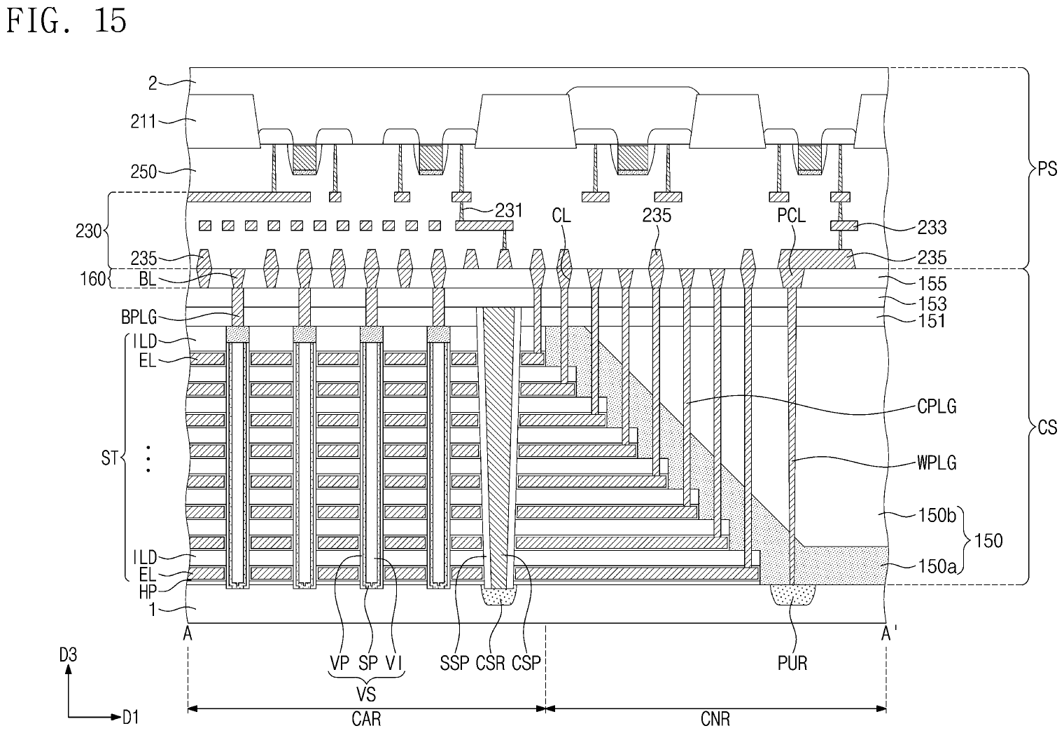

FIG. 15 is a sectional view illustrating a semiconductor device according to some embodiments of the inventive concepts. Referring to FIG. 15, the cell array structure CS may be provided on the first substrate 1 and may include the stacks ST, the vertical structures, and the interconnection structures CPLG, CL, WPLG, and PCL. The first substrate 1 and the cell array structure CS may have the same features as the first substrate 1 and the cell array structure CS described with reference to FIGS. 9 to 14A. The peripheral circuit structure PS may be on the cell array structure CS.

The second substrate 2 may be provided. The second substrate 2 may be a silicon wafer, a silicon-germanium wafer, a germanium wafer, or a single-crystalline epitaxial layer grown on a single-crystalline silicon wafer. As an example, the second substrate 2 may be a silicon wafer of the first conductivity type (e.g., p-type) and may include well regions.

The peripheral circuit structure PS may include peripheral circuits, which may be integrated on the second substrate 2, and a second insulating gapfill layer 250, which may be provided to cover the peripheral circuits. The peripheral circuits may be the row and column decoders, the page buffer, and the control circuit described above, and may include NMOS and PMOS transistors, low- and high-voltage transistors, and resistors, which may be integrated on a surface of the second substrate 2. In greater detail, a device isolation layer 211 may be formed in the second substrate 2 to define active regions. Peripheral gate electrodes 223 may be on the active region of the second substrate 2, and a gate insulating layer may be interposed between the peripheral gate electrodes 223 and the active region. Source/drain regions 221 may be provided in portions of the second substrate 2 at both sides of the peripheral gate electrodes 223.

A peripheral circuit interconnection layer 230 may be connected to the peripheral circuits on the second substrate 2. The peripheral circuit interconnection layer 230 may include peripheral interconnection lines 233 and peripheral circuit contact plugs 231. The peripheral interconnection lines 233 may be electrically connected to the peripheral circuits through the peripheral circuit contact plugs 231. For example, the peripheral circuit contact plugs 231 and the peripheral interconnection lines 233 may be coupled to the NMOS and PMOS transistors.

The second insulating gapfill layer 250 may cover the peripheral gate electrodes 223, the peripheral circuit contact plugs 231, and the peripheral interconnection lines 233. The second insulating gapfill layer 250 may expose a portion of the peripheral circuit interconnection layer 230 (e.g., portions of the peripheral interconnection lines 233, which will be referred to as an exposure line 235). The second insulating gapfill layer 250 may include a plurality of stacked insulating layers. For example, the second insulating gapfill layer 250 may be formed of or include at least one of SiO, SiN, SiON, and/or low-k dielectric materials.

The cell array structure CS may be in direct contact with the peripheral circuit structure PS. For example, the cell array interconnection layer 160 of the cell array structure CS may be in contact with the peripheral circuit interconnection layer 230 of the peripheral circuit structure PS, as shown in FIG. 5. For example, the third interlayer insulating layer 155 may be in contact with the second insulating gapfill layer 250, and some of the bit lines and peripheral connection lines BL and PCL may be connected to the exposure lines 235. Here, the cell array interconnection layer 160 and the peripheral circuit interconnection layer 230 may form an intermetal hybrid bonding structure. In the present specification, a hybrid bonding structure may mean a bonding structure which is formed by two materials, which are of the same kind and are fused at an interface therebetween. For example, each of the bit lines and peripheral connection lines BL and PCL may be connected to a corresponding one of the exposure lines 235 to form a single object, and thus, there may be no observable or visible boundary between the bit lines BL and the exposure lines 235 and between the peripheral connection lines PCL and the exposure lines 235. For example, the bit lines and peripheral connection lines BL and PCL may be formed of the same material as the exposure lines 235, and in this case, there may be no interface between the bit lines BL and the exposure lines 235 and between the peripheral connection lines PCL and the exposure lines 235. That is, each of the bit lines and peripheral connection lines BL and PCL and a corresponding one of the exposure lines 235 may be provided as a single object.

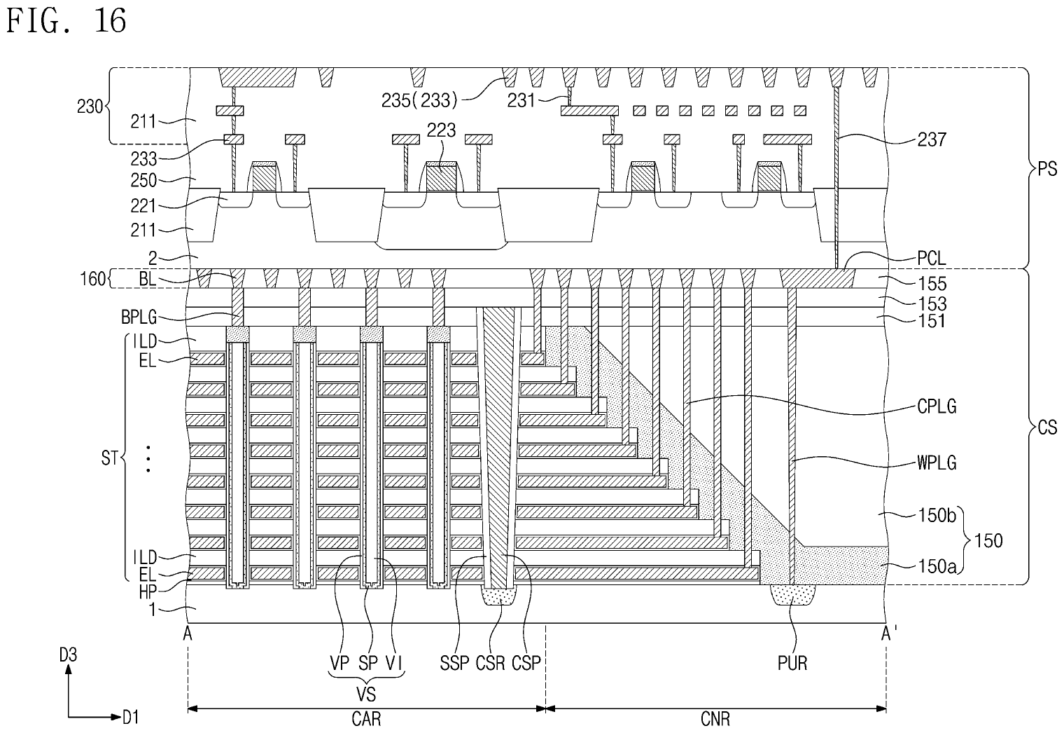

FIG. 16 is a sectional view illustrating a semiconductor device according to some embodiments of the inventive concepts. Referring to FIG. 16, the peripheral circuit structure PS may be on the cell array structure CS.

The cell array structure CS may be in direct contact with the peripheral circuit structure PS. For example, the third interlayer insulating layer 155 of the cell array structure CS and the second substrate 2 of the peripheral circuit structure PS may be in contact with each other. In an embodiment, the second substrate 2 may be a poly-crystalline or single-crystalline silicon layer, which may be deposited on the third interlayer insulating layer 155 using a deposition method. Here, for an electric connection between the cell array interconnection layer 160 and the peripheral circuit interconnection layer 230, the peripheral circuit interconnection layer 230 may further include a peripheral circuit via 237 that penetrates or extends through the second insulating gapfill layer 250 and the second substrate 2. The peripheral circuit vias 237 may connect the peripheral interconnection lines 233 to the peripheral connection lines PCL. Alternatively, the peripheral circuit vias 237 may connect the peripheral interconnection lines 233 to the bit lines BL or the connection lines CL.

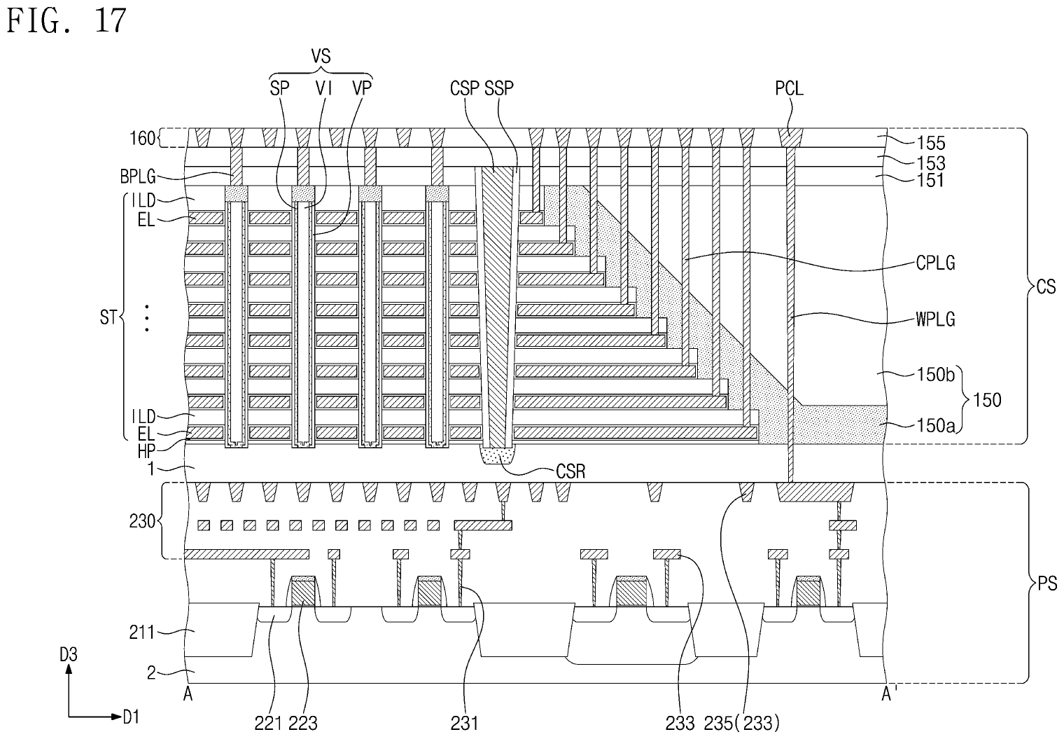

FIG. 17 is a sectional view illustrating a semiconductor device according to some embodiments of the inventive concept. Referring to FIG. 17, the cell array structure CS may be on the peripheral circuit structure PS. The cell array structure CS may be in direct contact with the peripheral circuit structure PS. For example, the second insulating gapfill layer 250 of the peripheral circuit structure PS and the first substrate 1 of the cell array structure CS may be in contact with each other. In some embodiments, the first substrate 1 may be a poly-crystalline or single-crystalline silicon layer, which may be deposited on the second insulating gapfill layer 250 using a deposition method. Here, to electrically connect the cell array interconnection layer 160 to the peripheral circuit interconnection layer 230, the well contact plug WPLG may penetrate the second interlayer insulating layer 153, the first interlayer insulating layer 151, the first insulating gapfill layer 150, and the first substrate 1, and the well contact plug WPLG may be coupled to the peripheral interconnection lines 233. In some embodiments, to electrically connect the cell array interconnection layer 160 to the peripheral circuit interconnection layer 230, the interconnection structure of the cell array structure CS may further include the connection contact plugs, which may be provided to penetrate the second insulating gapfill layer 250 and the first substrate 1 and may be coupled to the peripheral interconnection lines 233. The peripheral connection lines PCL may connect the connection contact plugs to the well contact plugs WPLG.

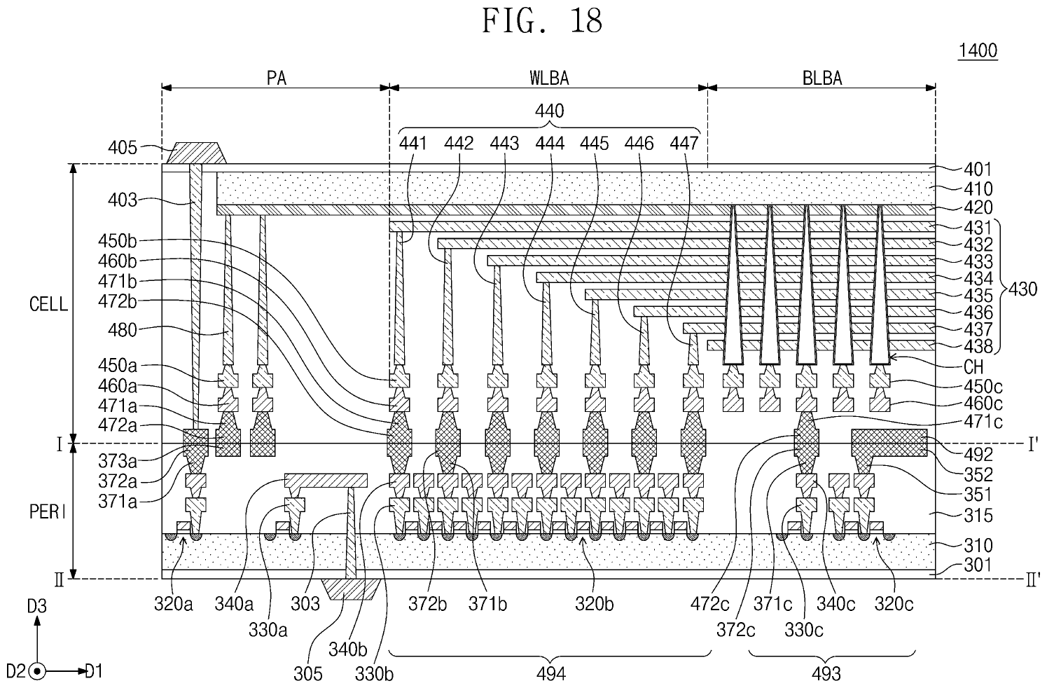

FIG. 18 is a sectional view illustrating a semiconductor device according to some embodiments of the inventive concepts. Referring to FIG. 18, the afore-described semiconductor device may be a memory device. A memory device 1400 may have a chip-to-chip (C2C) structure. The C2C structure may be formed by fabricating an upper chip with a cell region CELL on a first wafer, fabricating a lower chip with a peripheral region PERI on a second wafer different from the first wafer, and connecting the upper chip to the lower chip by a bonding method. The bonding method may mean a way of electrically connecting a bonding metal formed in the uppermost metal layer of the upper chip to a bonding metal formed in the uppermost metal layer of the lower chip. For example, in the case where the bonding metal is formed of copper, the bonding method may be a Cu-Cu bonding method, and the bonding metal may be formed of or include Al or W.

Each of the peripheral region PERI and the cell region CELL of the memory device 1400 may include an outer pad bonding region PA, a word line bonding region WLBA, and a bit line bonding region BLBA.

The peripheral region PERI may include a first substrate 310, an interlayer insulating layer 315, a plurality of circuit devices 320a, 320b, and 320c integrated on the first substrate 310, first metal layers 330a, 330b, and 330c, which may be respectively connected to the circuit devices 320a to 320c, and second metal layers 340a, 340b, and 340c formed on the first metal layers 330a to 330c.

The first substrate 310 may be a silicon wafer, a silicon-germanium wafer, a germanium wafer, or a single-crystalline epitaxial layer grown on a single-crystalline silicon wafer. In some embodiments, the first substrate 310 may be a silicon wafer of the first conductivity type (e.g., p-type) and may include well regions.

The circuit devices 320a to 320c, which are formed on the first substrate 310, may include a pre-charging control circuit, which may be configured to control data-programming steps on memory cells and to control some of cell strings. The circuit devices 320a to 320c may include source/drain regions separated from each other. The first metal layers 330a to 330c may be formed of or include a material (e.g., tungsten) having a relatively high resistance, and the second metal layers 340a to 340c may be formed of or include a material (e.g., copper) having a relatively low resistance. In the present specification, only the first and second metal layers 330a to 330c and 340a to 340c are illustrated and described, but the inventive concept is not limited to this example; for example, at least one metal layer may be further formed on the second metal layers 340a to 340c. At least one of the metal layers, which are formed on the second metal layers 340a to 340c, may be formed of a low resistance material (e.g., aluminum (Al)), which has an electric resistance lower than the material (e.g., copper (Cu)) of the second metal layers 340a to 340c.

The interlayer insulating layer 315 may be on the first substrate 310 and may cover the circuit devices 320a to 320c, the first metal layers 330a to 330c, and the second metal layers 340a to 340c, and the interlayer insulating layer 315 may be formed of or include at least one of insulating materials (e.g., SiO and SiN).

Lower bonding metals 371b and 372b may be formed on the second metal layer 340b of the word line bonding region WLBA. In the word line bonding region WLBA, the lower bonding metals 371b and 372b of the peripheral region PERI may be electrically connected to upper bonding metals 471b and 472b of the cell region CELL by a bonding method, and the lower and upper bonding metals 371b, 372b, 471b, and 472b may be formed of or include at least one of Al, Cu, or W. In addition, the upper bonding metals 471b and 472b of the cell region CELL may be referred to as first metal pads, and the lower bonding metals 371b and 372b of the peripheral region PERI may be referred to as second metal pads.

At least one memory block may be provided in the cell region CELL. The cell region CELL may include a second substrate 410 and a common source line 420.

The second substrate 410 may be formed of or include at least one of semiconductor materials and may be a silicon wafer, a silicon-germanium wafer, a germanium wafer, or a single crystalline epitaxial layer grown on a single crystalline silicon substrate. In some embodiments, the second substrate 410 may be a silicon wafer. Furthermore, the second substrate 410 may be formed of or include a semiconductor material, which may be doped with dopants of a first conductivity type (e.g., p-type), or an undoped or intrinsic semiconductor material.

A plurality of word lines 431 to 438 or 430 may be stacked on the second substrate 410 in the third direction D3, which may be perpendicular to a top surface of the second substrate 410. String selection lines and a ground selection line may be respectively on and below the word lines 430, and the word lines 430 may be between the string selection lines and the ground selection line.

In the bit line bonding region BLBA, a channel structure CH may be extended in a direction, which is perpendicular to the top surface of the second substrate 410, to penetrate the word lines 430, the string selection lines, and the ground selection line. The channel structure CH may include a data storage layer, a channel layer, and a gap-fill insulating layer, and the channel layer may be electrically connected to a first metal layer 450c and a second metal layer 460c. For example, the first metal layer 450c may be a bit line contact, and the second metal layer 460c may be a bit line. In some embodiments, the bit line 460c may be extended in the second direction D2, which may be parallel to the top surface of the second substrate 410.

A region, in which the channel structure CH and the bit line 460c are arranged, may be defined as the bit line bonding region BLBA. In the bit line bonding region BLBA, the bit line 460c may be electrically connected to the circuit devices 320c, which are provided in the peripheral region PERI to serve as a page buffer 493. In some embodiments, the bit line 460c may be connected to upper bonding metals 471c and 472c in the bit line bonding region BLBA, and the upper bonding metals 471c and 472c may be connected to lower bonding metals 371c and 372c, which are connected to the circuit devices 320c of the page buffer 493.

In the word line bonding region WLBA, the word lines 430 may be extended in the first direction D1, which is parallel to the top surface of the second substrate 410, and may be connected to a plurality of cell contact plugs 441 to 447 or 440. The cell contact plugs 440 may be connected to the word lines 430 through pads of the word lines 430, which may be extended to have different lengths from each other in the first direction D1. A first metal layer 450b and a second metal layer 460b may be sequentially connected to upper portions of the cell contact plugs 440, which are connected to the word lines 430. In the word line bonding region WLBA, the cell contact plugs 440 may be connected to the peripheral region PERI through the upper bonding metals 471b and 472b of the cell region CELL and the lower bonding metals 371b and 372b of the peripheral region PERI.

The cell contact plugs 440 may be electrically connected to the circuit devices 320b, which are formed in the peripheral region PERI to serve as a row decoder 494. An operation voltage of the circuit devices 320b serving as the row decoder 494 may be different from an operation voltage of the circuit devices 320c serving as the page buffer 493. In some embodiments, an operation voltage of the circuit devices 320c serving as the page buffer 493 may be higher than an operation voltage of the circuit devices 320b serving as the row decoder 494. The row decoder 494 may activate at least one of the word lines 430 in response to the control of the circuit devices 320a, 320b, and 320c of the first substrate 310.

A common source line contact plug 480 may be arranged in the outer pad bonding region PA. The common source line contact plug 480 may be formed of or include at least one of conductive materials (e.g., metallic materials, metal compounds, or polysilicon) and may be electrically connected to the common source line 420. A first metal layer 450a and a second metal layer 460a may be sequentially stacked on the common source line contact plug 480. In some embodiments, a region, in which the common source line contact plug 480, the first metal layer 450a, and the second metal layer 460a are provided, may be defined as the outer pad bonding region PA.

Meanwhile, input/output pads 305 and 405 may be in the outer pad bonding region PA. A lower insulating layer 301 may be formed under the first substrate 310 to cover a bottom surface of the first substrate 310, and a first input/output pad 305 may be formed on the lower insulating layer 301. The first input/output pad 305 may be connected to at least one of the circuit devices 320a, 320b, and 320c, which are in the peripheral region PERI, through a first input/output contact plug 303 and may be spaced apart from the first substrate 310 by the lower insulating layer 301. Furthermore, a side insulating layer may be between the first input/output contact plug 303 and the first substrate 310 and may electrically separate the first input/output contact plug 303 from the first substrate 310.

An upper insulating layer 401 may be formed on the second substrate 410 to cover the top surface of the second substrate 410, and a second input/output pad 405 may be disposed on the upper insulating layer 401. The second input/output pad 405 may be connected to at least one of the circuit devices 320a to 320c, which are disposed in the peripheral region PERI, through a second input/output contact plug 403.

The second substrate 410 and the common source line 420 may not be provided in a region in which the second input/output contact plug 403 is arranged. Furthermore, the second input/output pad 405 may not be overlapped with the word lines 430 in the third direction D3. The second input/output contact plug 403 may be separated from the second substrate 410 in a direction, which is parallel to the top surface of the second substrate 410, and may be provided to penetrate an interlayer insulating layer 415 of the cell region CELL and may be connected to the second input/output pad 405. The interlayer insulating layer 415 may correspond to the first insulating gapfill layer 150 described with reference to FIGS. 10A to 14A. For example, the interlayer insulating layer 415 may include a first insulating layer, which is formed of high-density plasma (HDP) oxide or silica glass and covers end portions of the word lines 430, and a second insulating layer, which is formed of TEOS oxide and covers the first insulating layer.

The first and second input/output pads 305 and 405 may be selectively formed. In some embodiments, the memory device 1400 may include only the first input/output pad 305, which is on the first substrate 310, or may include only the second input/output pad 405, which is on the second substrate 410. In some embodiments, the memory device 1400 may include both of the first and second input/output pads 305 and 405.

Metal patterns serving as dummy patterns may be provided in the uppermost metal layers of the cell and peripheral regions CELL and PERI and in the outer pad bonding region PA and the bit line bonding region BLBA, but in an embodiment, such metal patterns may not be formed in the uppermost metal layer.

The memory device 1400 may include an upper metal pattern 472a, which is formed in the uppermost metal layer of the cell region CELL and in the outer pad bonding region PA, and a lower metal pattern 373a, which is formed in the uppermost metal layer of the peripheral region PERI and in the outer pad bonding region PA, and here, the lower metal pattern 373a may be formed at a position corresponding to the upper metal pattern 472a to have the same shape as the upper metal pattern 472a. In the peripheral region PERI, the lower metal pattern 373a, which is formed in the uppermost metal layer of the peripheral region PERI, may not be connected to any contact. Similarly, the memory device 1400 may further include a lower metal pattern, which is formed in the uppermost metal layer of the peripheral region PERI and in the outer pad bonding region PA, and an upper metal pattern, which is formed in the upper metal layer of the cell region CELL and in the outer pad bonding region PA, and here, the lower metal pattern in the cell region CELL may be formed at a position corresponding to the upper metal pattern in the peripheral region PERI to have the same shape as the upper metal pattern in the peripheral region PERI.

The lower bonding metals 371b and 372b may be formed on the second metal layer 340b of the word line bonding region WLBA. In the word line bonding region WLBA, the lower bonding metals 371b and 372b of the peripheral region PERI may be electrically connected to the upper bonding metals 471b and 472b of the cell region CELL.

In some embodiments, a lower metal pattern 352 may be formed in the uppermost metal layer of the peripheral region PERI and in the bit line bonding region BLBA, and an upper metal pattern 492 may be formed in the uppermost metal layer of the cell region CELL, which corresponds to the lower metal pattern 352, and in the bit line bonding region BLBA. Here, the upper metal pattern 492 in the cell region CELL may have the same shape as the lower metal pattern 352 in the peripheral region PERI. Any contact may not be formed on the upper metal pattern 492, which is formed in the uppermost metal layer of the cell region CELL.

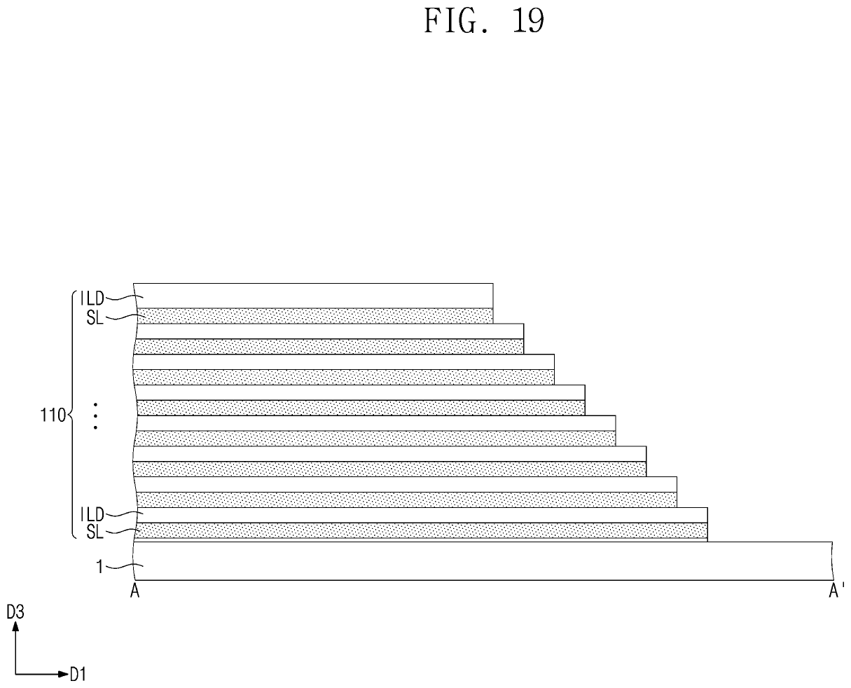

FIGS. 19 to 24 are sectional views illustrating a method of fabricating a semiconductor device, according to an embodiment of the inventive concept. Referring to FIGS. 9 and 19, the first substrate 1 including the cell array region CAR and the connection region CNR may be prepared.

A layered structure may be formed on the first substrate 1. The layered structure may be formed to cover the entire top surface of the first substrate 1. The layered structure may include sacrificial layers SL and insulating layers ILD, which are alternately and repeatedly stacked. The sacrificial layers SL and the insulating layers ILD may be formed by a thermal chemical vapor deposition process, a plasma-enhanced chemical vapor deposition process, or an atomic layer deposition process. The sacrificial layers SL may be formed of or include a material, which can be etched with an etch selectivity with respect to the insulating layers ILD. For example, the sacrificial layers SL and the insulating layers ILD may have a high etch selectivity in a wet etching process, which is performed using chemical solution, and may have a low etch selectivity in a dry etching process using etching gas. In some embodiments, the sacrificial layers SL and the insulating layers ILD may be formed of or include insulating materials having an etch selectivity with respect to each other. For example, the sacrificial layers SL may be formed of or include silicon nitride (SiN), and the insulating layers ILD may be formed of or include silicon oxide (SiO).

Thereafter, a patterning process may be performed on the layered structure to form a mold structure 110 on the first substrate 1. The mold structure 110 may be formed by performing a trimming process on the layered structure. Here, the trimming process may include forming a mask pattern on the layered structure, etching a portion of the layered structure, reducing a horizontal area of the mask pattern, and removing the mask pattern, and here, the steps of etching a portion of the layered structure and reducing a horizontal area of the mask pattern may be repeated several times, before the step of removing the mask pattern. As a result of the trimming process, the mold structure 110 may have a stepwise structure on the connection region CNR of the first substrate 1.

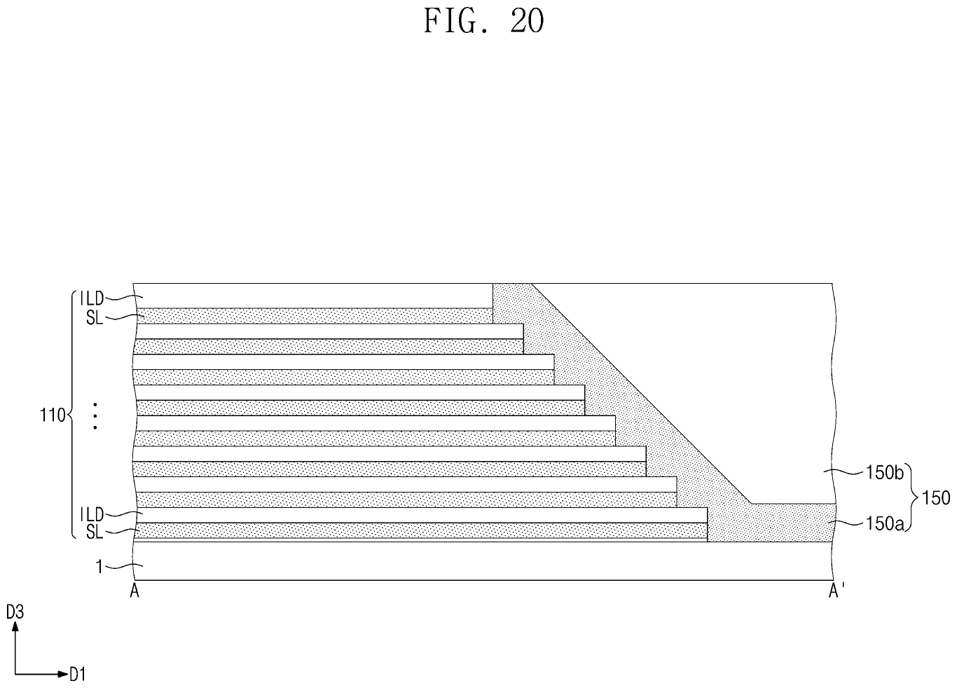

Referring to FIGS. 9 and 20, the first insulating gapfill layer 150 may be formed on the first substrate 1 provided with the mold structure 110. Hereinafter, the formation of the first insulating gapfill layer 150 will be described in more detail below.

The first insulating layer 150a may be deposited on the first substrate 1. For example, the deposition process of the first insulating layer 150a may include a high-density plasma chemical vapor deposition (HDP-CVD) process. In the case where the first insulating layer 150a is formed by the HDP-CVD process, the first insulating layer 150a may be formed to have a high density and a high uniformity. The first insulating layer 150a may cover and conform to the top surface of the first substrate 1 and the mold structure 110. The first thickness of the first insulating layer 150a may be larger than the second thickness of one stepped portion of the stepwise structure of the mold structure 110. The first insulating layer 150a may be formed of or include an insulating material having an etch selectivity with respect to the sacrificial layers SL. The first insulating layer 150a may be doped with the first dopants.

The second insulating layer 150b may be deposited on the first insulating layer 150a. For example, the deposition process of the second insulating layer 150b may include a plasma-enhanced chemical vapor deposition (PE-CVD) process. The second insulating layer 150b, which is formed through the PE-CVD process, may be deposited at a high deposition rate. Since the second insulating layer 150b is formed through the PE-CVD process, the density and uniformity of the second insulating layer 150b may be lower than those of the first insulating layer 150a. The second insulating layer 150b may be formed to cover (e.g., cover fully) the mold structure 110 and the first insulating layer 150a. For example, the entire top surface of the second insulating layer 150b may be located at a level higher than the first insulating layer 150a. The second insulating layer 150b may be doped with the second dopants.

Thereafter, the first insulating gapfill layer 150 may be formed by performing a planarization process on the first and second insulating layers 150a and 150b.

In some embodiments, the first insulating layer 150a, which has a high density and a high uniformity, may be formed near the mold structure 110 having a complicated surface shape. Thus, it may be possible to prevent the first insulating gapfill layer 150 from being damaged by the shape of the mold structure 110 and to reduce a failure rate in a process of fabricating a semiconductor device. Furthermore, a portion of the first insulating gapfill layer 150, which is adjacent to the mold structure 110, may be formed as the first insulating layer 150a, and a remaining portion of the first insulating gapfill layer 150 may be formed as the second insulating layer 150b formed by the PE-CVD process. Thus, it may be possible to reduce a process time in a process of forming the first insulating gapfill layer 150 and to form the second insulating layer 150b at a low temperature. That is, it may be possible to reduce a failure rate, a process time, and a process temperature in a process of fabricating a semiconductor device.

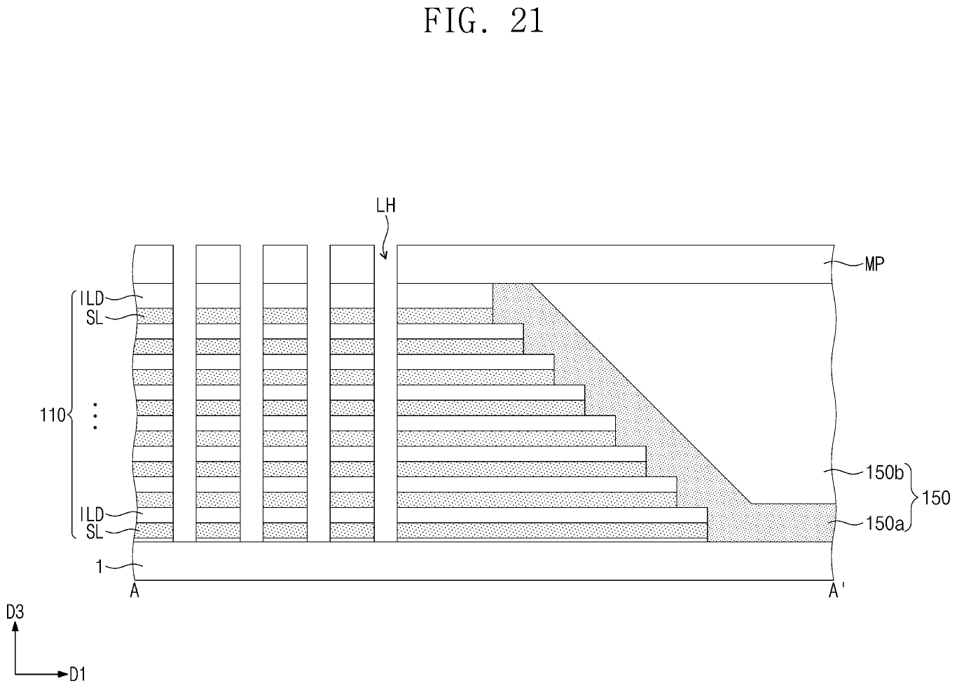

Referring to FIGS. 9 and 21, a hard mask layer MP may be formed to have openings exposing the mold structure 110. The hard mask layer MP may be formed to cover the entire top surface of the first substrate 1. Vertical holes LH exposing the first substrate 1 may be formed in the mold structure 110 by anisotropically etching portions of the mold structure 110, which are exposed through the openings of the hard mask layer MP. The vertical holes LH may be arranged in a specific direction or in a zigzag shape, when viewed in a plan view. Here, an anisotropic etching process on the mold structure 110 may be a plasma etching process, a reactive ion etching (RIE) process, an inductively-coupled plasma reactive ion etching (ICP-RIE) process, or an ion beam etching (IBE) process.

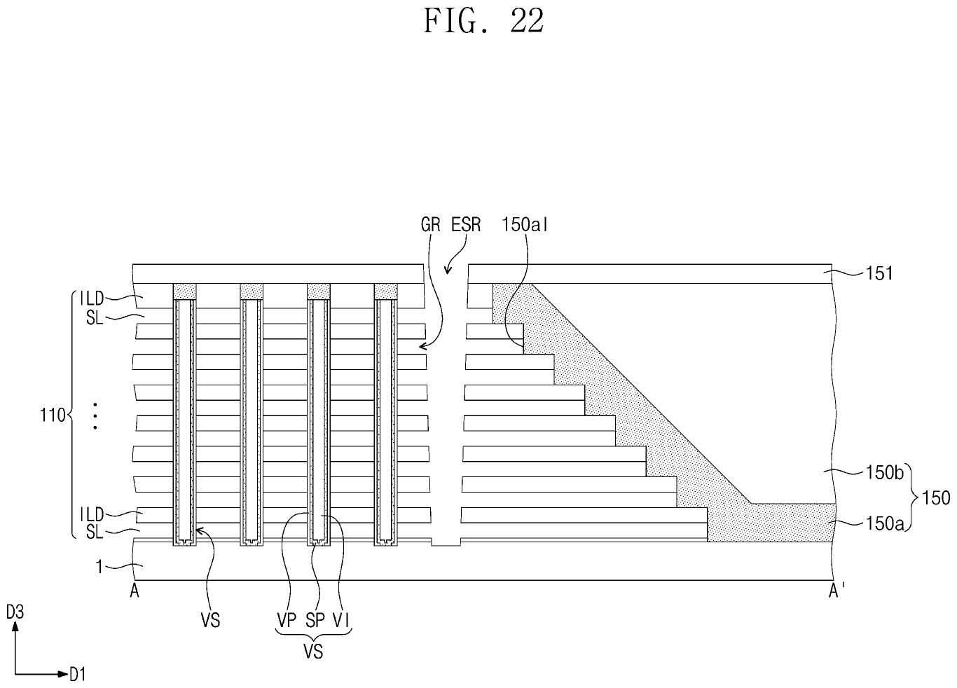

Referring to FIGS. 9 and 22, the vertical structures VS may be formed in the vertical holes LH of FIG. 21. The formation of the vertical structures VS may include forming a semiconductor spacer to expose the first substrate 1 and cover the side surfaces of the openings and forming a semiconductor body portion connected to the first substrate 1. The vertical structures VS may be connected to the first substrate 1. In addition, a conductive pad may be provided on the vertical structure VS or in an upper portion of the vertical structure VS. The conductive pad may be an impurity region doped with dopants or may be formed of or include a conductive material.

Before the formation of the vertical structures VS in the vertical holes LH, the vertical insulating pattern VP may be formed in the vertical holes LH. The vertical insulating pattern VP may be composed of one or more thin films. The vertical insulating pattern VP may be a portion of the data storing layer.

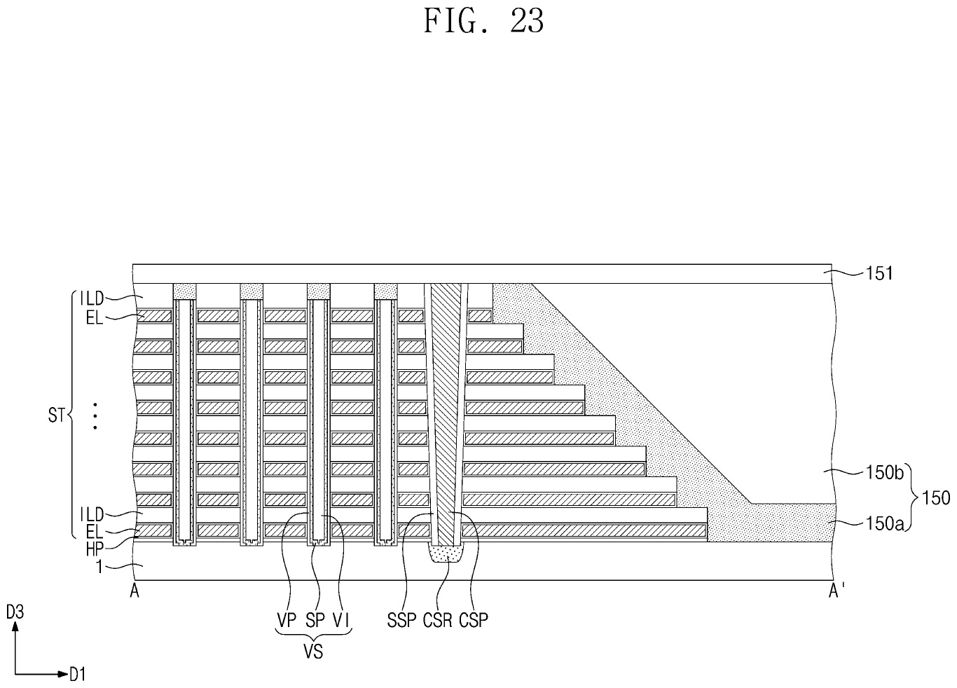

Next, after the formation of the vertical structures VS, the stacks ST, which include the electrodes EL vertically stacked on the first substrate 1, may be formed by performing a process of replacing the sacrificial layers of the mold structures with the electrodes. This will be described in greater detail with reference to FIGS. 22 and 23.

Referring further to FIGS. 9 and 22, the first interlayer insulating layer 151 may be formed on the first insulating gapfill layer 150 to cover the top surfaces of the vertical structures VS. After the formation of the first interlayer insulating layer 151, electrode separation regions ESR may be formed to penetrate the mold structure 110 of FIG. 21 and expose the first substrate 1. The electrode separation regions ESR exposing side surfaces of the mold structure 110 may be formed by anisotropically etching the mold structure 110.

The electrode separation regions ESR may be extended from the cell array region CAR to the connection region CNR in the first direction D1. Some of the electrode separation regions ESR may have a short length in the first direction D1, compared with the others of the electrode separation regions ESR. As a result of the formation of the electrode separation regions ESR, a plurality of sub-mold structures, which are spaced apart from each other in the second direction D2, may be formed.

Thereafter, gate regions GR may be formed by removing the sacrificial layers SL exposed through the electrode separation regions ESR. The gate regions GR may be formed by isotropically etching the sacrificial layers SL using an etch recipe having an etch selectivity with respect to the insulating layers ILD, the vertical structures VS, and the first substrate 1. Here, the sacrificial layers SL may be completely removed by an isotropic etching process. Thus, the first insulating layer 150a of the first insulating gapfill layer 150 may be exposed by the gate regions GR. In the case where the sacrificial layers SL are formed of silicon nitride (SiN) and the insulating layers ILD are formed of silicon oxide (SiO), the etching step may be performed by an isotropic etching method using etching solution containing phosphoric acid. The vertical structures VS may prevent the insulating layers ILD defining the gate regions GR from being collapsed when the gate regions GR are formed. The gate regions GR may be empty spaces, which may be provided between vertically adjacent ones of the insulating layers ILD to partially expose the side surfaces of the vertical structures VS. Furthermore, the gate regions GR may be formed to expose the side surfaces of the first insulating gapfill layer 150 or side surfaces 150al of the first insulating layer 150a.

According to some embodiments of the inventive concept, the first insulating layer 150a of the first insulating gapfill layer 150 may be provided to be in contact with the mold structure 110 of FIG. 21. When the sacrificial layers SL of the mold structure 110 are removed by the etching solution, the etching solution may be in contact with the first insulating layer 150a. However, since the first insulating layer 150a is formed of a material having a high density and a high uniformity, the first insulating layer 150a may not be damaged by the etching solution. Furthermore, the first insulating layer 150a may be formed to be in close contact with the mold structure 110, and thus, the etching solution may not infiltrate into a space between the first insulating layer 150a and the insulating layers ILD. That is, a method of reduce a failure rate in a process of fabricating a semiconductor device.

Referring further to FIGS. 9 and 23, the stack ST may be formed on the first substrate 1 by forming the horizontal insulating patterns HP and the electrodes EL in the gate regions GR. In greater detail, the formation of the horizontal insulating patterns HP and the electrodes EL may include sequentially depositing a horizontal insulating layer, a barrier metal layer, and a metal layer on the mold structure 110 (e.g., see FIG. 21) with the gate regions GR and anisotropically etching the barrier metal layer and the metal layer.

After the formation of the electrodes EL, the common source regions CSR may be formed in the first substrate 1, which is exposed through the electrode separation regions ESR, and the electrode separation regions ESR may be filled with an insulating material. The common source regions CSR may include n-type dopants. Furthermore, the common source plug CSP, which is coupled to the common source region CSR, may be formed in the electrode separation region ESR filled with the insulating material.

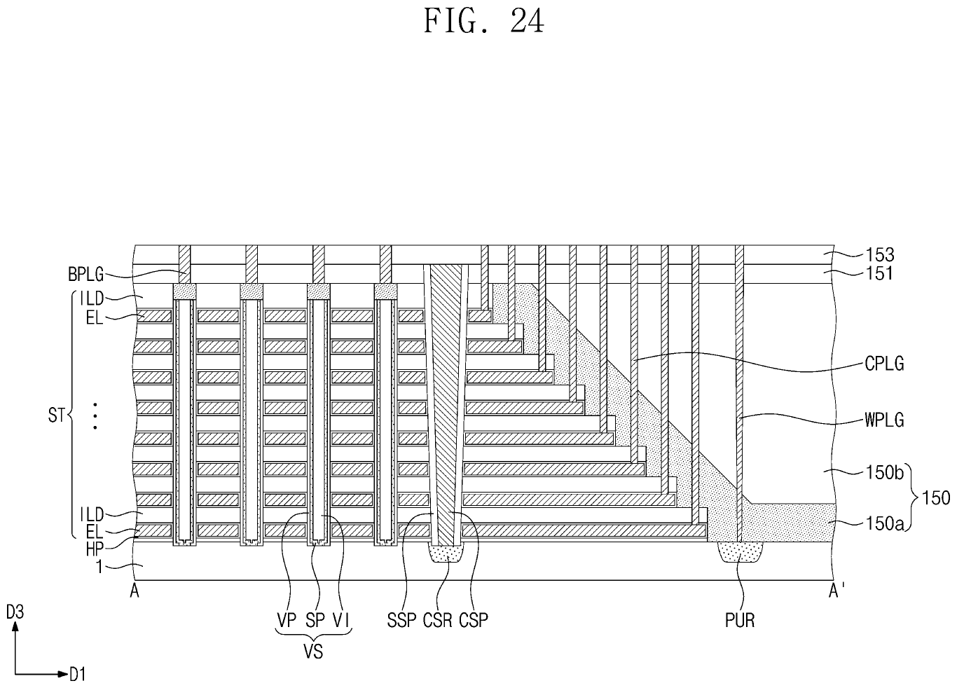

Referring further to FIGS. 9 and 24, the second interlayer insulating layer 153 may be formed on the first interlayer insulating layer 151. Next, a patterning process may be performed on the second interlayer insulating layer 153, the first interlayer insulating layer 151, and the first insulating gapfill layer 150 to form contact holes. In greater detail, cell contact holes may be formed to expose the end portions of the electrodes EL, respectively, in the connection region CNR. Connection contact holes may be formed to expose the first substrate 1 in the connection region CNR. Bit line contact holes may be formed to expose the vertical structures VS in the cell array region CAR. Here, an etch rate of the first insulating layer 150a of the first insulating gapfill layer 150 may be equal or similar to an etch rate of the second insulating layer 150b. To achieve this, the kinds and concentrations of the first and second dopants, which are respectively contained in the first and second insulating layers 150a and 150b, may be adjusted. Since the first and second insulating layers 150a and 150b are etched at the same etch rate, a process of forming the cell contact holes, the connection contact holes, and the bit line contact holes may be more easily performed.

Thereafter, the bit line contact plugs BPLG, the cell contact plugs CPLG, and the well contact plugs WPLG may be formed by filling the contact holes with a conductive material.

Referring to FIGS. 9 and 10A, the third interlayer insulating layer 155 may be formed on the second interlayer insulating layer 153. On the second interlayer insulating layer 153, the third interlayer insulating layer 155 may cover the bit line contact plugs BPLG, the cell contact plugs CPLG, and the well contact plugs WPLG.

Next, a patterning process may be performed on the third interlayer insulating layer 155 to form first openings exposing the bit line contact plugs BPLG in the cell array region CAR and form second openings exposing the cell and well contact plugs CPLG and WPLG in the connection region CNR, and then, the bit lines BL, the connection lines CL, and the peripheral connection lines PCL may be formed by filling the first and second openings of the third interlayer insulating layer 155 with a conductive material.

In semiconductor devices according to some embodiments of the inventive concepts, an insulating gapfill layer may not be damaged (or may not be as damaged) by a stress, which may be caused by the shape, deformation, or expansion of a stack. In addition, there may be no interfacial defect between a first insulating layer and the stack, and a dislocation issue by the interfacial defect may not occur in the first insulating layer. That is, a semiconductor device with improved structural stability may be provided.

In methods of fabricating semiconductor devices according to some embodiments of the inventive concepts, it may be possible to prevent the insulating gapfill layer from being damaged by a complicated surface shape of a mold structure and to reduce a failure rate in a process of fabricating a semiconductor device. In addition, it may be possible to reduce a process time in a process of forming the insulating gapfill layer and to form a second insulating layer at a low temperature. That is, it may be possible to reduce a failure rate, a process time, and/or a process temperature in a process of fabricating a semiconductor device.

While some examples of embodiments of the inventive concepts have been particularly shown and described, it will be understood by one of ordinary skill in the art that variations in form and detail may be made therein without departing from the scope of the attached claims.

What is claimed is:

1. A semiconductor device, comprising:
a substrate including a cell array region and a connection region;
a stack including electrodes, which are vertically stacked on the substrate, and which have a staircase structure in the connection region;
channel regions provided on the cell array region that extend vertically through the stack; and
a planarization insulating layer that covers the stack in the connection region,
wherein the planarization insulating layer comprises:
a first insulating layer in contact with the stack; and
a second insulating layer that covers the first insulating layer,
wherein the first insulating layer comprises high-density plasma (HDP) oxide, which is doped with first dopants, and
wherein the second insulating layer comprise tetraethyl orthosilicate (TEOS) oxide, which is doped with second dopants.

2. The semiconductor device of claim 1, wherein the first dopants comprise boron (B), phosphorus (P), carbon (C), nitrogen (N), or silicon (Si), and
wherein the second dopants comprise boron (B), phosphorus (P), carbon (C), nitrogen (N), or silicon (Si).

3. The semiconductor device of claim 1, wherein the second insulating layer is spaced apart from the stack by the first insulating layer.

4. The semiconductor device of claim 1, wherein the first insulating layer covers and conforms to the staircase structure of the stack.

5. The semiconductor device of claim 1, wherein an interface between the first insulating layer and the second insulating layer has a wavy shape.

6. The semiconductor device of claim 1, wherein a thickness of the first insulating layer is greater than a thickness of one stepped portion of the staircase structure of the stack.

7. The semiconductor device of claim 1, wherein an etch rate of the first insulating layer is equal or similar to an etch rate of the second insulating layer.

8. The semiconductor device of claim 1, wherein a density of the first insulating layer is higher than a density of the second insulating layer.

9. The semiconductor device of claim 1, wherein the planarization insulating layer further comprises:
a third insulating layer on the second insulating layer; and
a fourth insulating layer covering the third insulating layer,
wherein the third insulating layer comprises high-density plasma (HDP) oxide or silica glass, which is doped with the first dopants, and
wherein the fourth insulating layer comprises tetraethyl orthosilicate (TEOS) oxide, which is doped with the second dopants.

10. The semiconductor device of claim 1, further comprising:
penetration plugs, which are provided on the connection region and extend vertically through the planarization insulating layer and are connected to the electrodes; and
interconnection patterns, which are on the planarization insulating layer and are connected to the penetration plugs,
wherein the stack further comprises insulating patterns interposed between the electrodes.

11. A semiconductor device, comprising:
a substrate including a cell array region and a connection region;
a stack including electrodes and insulating patterns, which are vertically and alternately stacked on the substrate, an end portion of the stack on the connection region having a staircase structure;
channel regions vertically extending through the stack, in the cell array region;
a planarization insulating layer that covers the stack, in the connection region;
penetration plugs provided on the connection region that vertically extend through the planarization insulating layer and are connected to the electrodes; and
interconnection patterns on the planarization insulating layer and connected to the penetration plugs,
wherein the planarization insulating layer comprises:
a first insulating layer that covers a top surface of the substrate and the end portion of the stack; and
a second insulating layer, which is on the first insulating layer and is spaced apart from the stack by the first insulating layer,
wherein an interface between the first insulating layer and the second insulating layer has a wavy shape, and
wherein a density of the first insulating layer is higher than a density of the second insulating layer.

12. The semiconductor device of claim 11, wherein the first insulating layer comprises high-density plasma (HDP) oxide or silica glass, and
wherein the second insulating layer comprises tetraethyl orthosilicate (TEOS) oxide.

13. The semiconductor device of claim 12, wherein the first insulating layer is doped with first dopants, and
wherein the second insulating layer is doped with second dopants.

14. The semiconductor device of claim 13, wherein the first dopants comprise boron (B), phosphorus (P), carbon (C), nitrogen (N), or silicon (Si), and
wherein the second dopants comprise boron (B), phosphorus (P), carbon (C), nitrogen (N), or silicon (Si).

15. The semiconductor device of claim 11, wherein the first insulating layer covers and conforms to the staircase structure of the stack.

16. The semiconductor device of claim 11, wherein a thickness of the first insulating layer is greater than a thickness of one stepped portion of the staircase structure of the stack.

17. The semiconductor device of claim 11, wherein an etch rate of the first insulating layer is equal or similar to an etch rate of the second insulating layer.

18. The semiconductor device of claim 11, wherein the planarization insulating layer further comprises:
a third insulating layer on the second insulating layer; and
a fourth insulating layer covering the third insulating layer,
wherein the third insulating layer comprises high-density plasma (HDP) oxide or silica glass, which is doped with first dopants, and
wherein the fourth insulating layer comprises tetraethyl orthosilicate (TEOS) oxide, which is doped with second dopants.

19. An electronic system, comprising:
a semiconductor device comprising a substrate including a cell array region and a connection region, a stack including electrodes, which are vertically stacked on the substrate, and having a staircase structure on the connection region, a plurality of channel regions, which are provided on the cell array region and which vertically extend through the stack, a planarization insulating layer that covers the stack, and an input/output pad electrically connected to a peripheral circuit; and
a controller, which is electrically connected to the semiconductor device through the input/output pad and is configured to control the semiconductor device,
wherein the planarization insulating layer comprises:
a first insulating layer that covers the staircase structure of the stack; and
a second insulating layer on the first insulating layer and spaced apart from the stack by the first insulating layer,
wherein a density of the first insulating layer is higher than a density of the second insulating layer,
wherein a thickness of the first insulating layer is larger than a thickness of one stepped portion of the staircase structure of the stack, and
wherein the first insulating layer and the second insulating layer comprise different materials from each other.

20. The electronic system of claim 19, wherein the first insulating layer comprises high-density plasma (HDP) oxide or silica glass, which is doped with first dopants, and
wherein the second insulating layer comprises tetraethyl orthosilicate (TEOS) oxide, which is doped with second dopants.
